(19) United States
(12) Patent Application Publication
(10) Pub. No.: US 2025/0194307 A1
(43) Pub. Date: Jun. 12, 2025

(54) LENSES FORMED BY ADDITIVE MANUFACTURING FOR LIGHT-EMITTING DIODE PACKAGES

(71) Applicant: CreeLED, Inc., Durham, NC (US)

(72) Inventors: Andre Pertuit, Raleigh, NC (US); Michael Check, Holly Springs, NC (US); Colin Blakely, Raleigh, NC (US); David Suich, Durham, NC (US); Joseph G. Sokol, Durham, NC (US); Robert Wilcox, Rolesville, NC (US)

(21) Appl. No.: 18/531,858

(22) Filed: Dec. 7, 2023

(51) Int. Cl. H01L 33/54; H01L 25/13; H01L 33/56

(52) U.S. Cl. CPC H10H 20/853; H01L 25/13; H10H 20/0362; H10H 20/854

(57) ABSTRACT

Light-emitting diodes (LEDs), and more particularly, lenses formed by additive manufacturing for LED packages are disclosed. Additive manufacturing is used to progressively cure precursor materials for lenses in directions away from corresponding submounts. Progressively curing precursor materials may be performed in a layer-by-layer manner or in a continuous manner. Such additive manufacturing allows complex lens shapes that form primary optics and encapsulation for LED chips of LED packages. Complex shapes include pockets of air or other materials embedded within lens materials, pockets formed about LED chips, progressively increasing lens widths, Fresnel shapes, and/or asymmetric shapes, among others.

### FIELD OF THE DISCLOSURE

The present disclosure relates to light-emitting diodes (LEDs), and more particularly, to lens formed by additive manufacturing for LED packages.

### BACKGROUND

Solid-state lighting devices such as light-emitting diodes (LEDs) are increasingly used in both consumer and commercial applications. LEDs have been widely adopted in various illumination contexts, as well as for backlighting of liquid crystal displays and for providing sequentially illuminated LED displays. Illumination applications include automotive headlamps, roadway lamps, stadium lights, light fixtures, flashlights, and various indoor, outdoor, and specialty lighting contexts. Desirable characteristics of LED devices according to various end uses include high luminous efficacy, uniform color point over an illuminated area, long lifetime, wide color gamut, and compact size.

LEDs are solid-state devices that convert electrical energy to light and generally include one or more active layers of semiconductor material (or an active region) arranged between oppositely doped n-type and p-type layers. When a bias is applied across the doped layers, holes and electrons are injected into the one or more active layers where they recombine to generate emissions such as visible light or ultraviolet emissions. An LED chip typically includes an active region that may be fabricated, for example, from silicon carbide, gallium nitride, gallium phosphide, indium phosphide, aluminum nitride, gallium arsenide-based materials, and/or from organic semiconductor materials. Photons generated by the active region are initiated in all directions.

LED packages typically include integrated primary optics that shape LED chip emissions into desired LED package emission profiles. Secondary optics such as secondary lenses and/or reflectors are sometimes used with LED packages to further direct desired output beam characteristics. However, secondary optics may increase the size, cost, and complexity of lighting devices, and may introduce some optical losses. Another limitation associated with LED lighting devices is the cost and complexity of manufacturing secondary optics, for example. This limitation becomes more pronounced when manufacturing a large number of secondary optics having a desired shape or size.

The art continues to seek improved LEDs and solid-state lighting devices having desirable illumination characteristics capable of overcoming challenges associated with conventional lighting devices.

### SUMMARY

The present disclosure relates to light-emitting diodes (LEDs), and more particularly, to lens formed by additive manufacturing for LED packages. Additive manufacturing is used to progressively cure precursor materials for lenses in directions away from corresponding submounts. Progressively curing precursor materials may be performed in a layer-by-layer manner or in a continuous manner. Such additive manufacturing allows complex lens shapes that form primary optics and encapsulation for LED chips of LED packages. Complex shapes include pockets of air or other materials embedded within lens materials, pockets formed about LED chips, progressively increasing lens widths, Fresnel shapes, and/or asymmetric shapes, among others.

In one aspect, an LED package comprises: a support structure; an LED chip on the support structure; and a lens on the support structure, the lens forming an encapsulant for the LED chip, the lens forming a pocket entirely embedded within a continuous material of the lens, and the pocket forming an index of refraction step with the continuous material of the lens. In certain embodiments, a longest dimension of the pocket is in a range from 25 microns (μm) to 4000 μm. In certain embodiments, the pocket forms an ellipsoid shape within the lens. In certain embodiments, the pocket forms an air pocket within the lens. In certain embodiments, the pocket retains a fill material that is different than the continuous material of the lens. In certain embodiments, the lens forms a base portion on the support structure and a top portion that is spaced from the support structure by the base portion, the base portion having a width that increases with distance from the support structure. In certain embodiments, a top surface of the top portion of the lens forms a Fresnel lens. In certain embodiments, the pocket is a first pocket and the lens further forms a second pocket that is embedded within the continuous material of the lens. In certain embodiments, the pocket is one of an array of pockets that form a periodic array within the continuous material of the lens. In certain embodiments, the lens forms an asymmetric shape relative to the submount.

In another aspect, an LED package comprises: a support structure; an LED chip on the support structure; and a lens formed directly on the support structure, the lens forming a pocket on the support structure that separates the LED chip from a material of the lens. In certain embodiments, the pocket forms a hemiellipsoid shape about the LED chip. In certain embodiments, the pocket forms a cuboid shape. In certain embodiments, the pocket forms an air pocket about the LED chip. In certain embodiments, the pocket retains a fill material that is different than the material of the lens.

In another aspect, a method of manufacturing an LED package comprises: providing a submount with an LED chip mounted thereon; and forming a lens on the submount and the LED chip by additive formation, the additive formation comprising progressively curing a precursor material of the lens in a direction away from the submount. In certain embodiments, progressively curing the precursor material comprises progressively curing progressive layers of the precursor material in the direction away from the submount. In certain embodiments, progressively curing the precursor material comprises continuously curing the precursor material in the direction away from the submount. The method may further comprise forming a pocket in lens, the pocket comprising air or a fill material that is a different material than the lens. In certain embodiments, the submount and LED chip are part of an LED panel, and multiple lenses are formed by progressively curing the precursor material of the lens in the direction away from the submount.

In another aspect, any of the foregoing aspects individually or together, and/or various separate aspects and features as described herein, may be combined for additional advantage. Any of the various features and elements as disclosed herein may be combined with one or more other disclosed features and elements unless indicated to the contrary herein.

Those skilled in the art will appreciate the scope of the present disclosure and realize additional aspects thereof after reading the following detailed description of the preferred embodiments in association with the accompanying drawing figures.

### BRIEF DESCRIPTION OF THE DRAWING FIGURES

The accompanying drawing figures incorporated in and forming a part of this specification illustrate several aspects of the disclosure and, together with the description, serve to explain the principles of the disclosure.

FIG. 1A shows a simplified cross-sectional view of an exemplary light-emitting diode (LED) package with an LED chip encapsulated by a lens that forms an integrated primary optic.

FIG. 1B shows a top view of an LED panel having a plurality of the LED packages from FIG. 1 formed over a top surface of a panel or submount according to aspects of the present disclosure.

FIG. 1C illustrates a cross-sectional view of a portion of the LED panel of FIG. 1B having a plurality of the LED packages fabricated according to aspects of the present disclosure.

FIG. 2 shows a conventional molding method for fabrication of lenses and LED packages of an LED panel.

FIG. 3A shows a submount after formation of a first cured layer of lenses using a layer-by-layer additive printing method according to aspects of the present disclosure.

FIG. 3B illustrates the submount of FIG. 3A as seen after formation of a second cured layer of lenses using the layer-by-layer additive printing method.

FIG. 3C illustrates the submount of FIG. 3B as seen after repeating the steps of FIG. 3B a selected number of times to fabricate lenses using the layer-by-layer additive printing method.

FIG. 3D illustrates the submount of FIG. 3C forming an LED panel having a plurality of LED packages as manufactured using the layer-by-layer additive printing method.

FIG. 4 illustrates an exemplary process flow diagram describing the general fabrication steps of the layer-by-layer additive printing method of FIGS. 3A to 3D.

FIG. 5A shows a submount at a fabrication step after a first cured layer of lenses is formed using an injection printing method according to aspects of the present disclosure.

FIG. 5B illustrates the submount of FIG. 5A as seen after formation of a second cured layer of lenses using the injection printing method.

FIG. 5C illustrates the submount of FIG. 5B as seen after repeating the step of FIG. 5B a selected number of times to fabricate lenses using the injection printing method.

FIG. 5D illustrates the submount of FIG. 5C forming an LED panel having a plurality of LED packages using the injection printing method.

FIG. 6 illustrates an exemplary process flow diagram describing the general fabrication steps of the injection printing method of FIGS. 5A to 5D.

FIG. 7A shows a submount after a first cured layer of lenses is fabricated during additive digital light processing (DLP) according to aspects of the present disclosure.

FIG. 7B illustrates the submount of FIG. 7A after formation of a second cured layer of lenses as part of a subsequent fabrication step of the additive DLP method.

FIG. 7C illustrates repeating the fabrication step of FIG. 7B a selected number of times to complete fabrication of the lenses.

FIG. 8 illustrates an exemplary process flow diagram describing the general fabrication steps of the additive DLP method of FIGS. 7A to 7C.

FIG. 9A shows a submount positioned relative to a resin tank to form a first raster layer of lenses in a layer-by-layer stereolithography (SLA) printing method according to aspects of the present disclosure.

FIG. 9B illustrates the submount of FIG. 9A after formation of a second raster layer of lenses as part of the layer-by-layer SLA printing method.

FIG. 9C illustrates fabrication of the lenses by repeating the fabrication step as illustrated by FIG. 9B a selected number of times as part of the layer-by-layer SLA printing method.

FIG. 10 illustrates an exemplary process flow diagram describing the general fabrication steps of the layer-by-layer SLA printing method of FIGS. 9A to 9C.

FIG. 11A shows a submount with LED chips positioned for formation of lenses by an additive liquid crystal display (LCD) printing method according to aspects of the present disclosure.

FIG. 11B illustrates the submount after formation of another LCD cured layer as part of a subsequent fabrication step of the additive LCD printing method.

FIG. 11C illustrates repeating the fabrication step of FIG. 11B a selected number of times to complete fabrication of the lenses.

FIG. 12 illustrates an exemplary process flow diagram describing the general fabrication steps of the LCD printing method of FIGS. 11A to 11C.

FIG. 13 is a perspective view of an LED package with a lens having a pocket formed within the lens according to principles of the present disclosure.

FIG. 14 is a perspective view of an LED package that is similar to the LED package of FIG. 13, except a pocket in a lens is formed with a hemiellipsoid shape.

FIG. 15 is a perspective view of an LED package that is similar to the LED package of FIG. 13, except a pocket is formed proximate a submount.

FIG. 16 is a perspective view of an LED package that is similar to the LED package of FIG. 13, except a top surface of a lens forms a Fresnel lens.

FIG. 17 is a perspective view of an LED package that is similar to the LED package of FIG. 15 except a pocket is formed proximate a submount with a cuboid shape.

FIG. 18 is a perspective view of an LED package that is similar to the LED package of FIG. 13 for embodiments with a lens that is generally curved.

FIG. 19 is a perspective view of an LED package that is similar to the LED package of FIG. 18 for embodiments with multiple pockets.

FIG. 20 is a perspective view of an LED package that is similar to the LED package of FIG. 19 for embodiments where multiple pockets form a periodic array within a lens.

FIG. 21 is a perspective view of an LED package that is similar to the LED package of FIG. 19 for embodiments that include multiple pockets with ellipsoid shapes.

FIG. 22 is a perspective view of an LED package that is similar to the LED package of FIG. 13 for embodiments where a pocket forms a non-circular geometric shape.

FIG. 23 is a cross-sectional view of an LED package that is similar to the LED package of FIG. 13 for embodiments with a lens having an asymmetric shape.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. Likewise, it will be understood that when an element such as a layer, region, or substrate is referred to as being “over” or extending “over” another element, it can be directly over or extend directly over the other element or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

Embodiments are described herein with reference to schematic illustrations of embodiments of the disclosure. As such, the actual dimensions of the layers and elements can be different, and variations from the shapes of the illustrations as a result, for example, of manufacturing techniques and/or tolerances, are expected. For example, a region illustrated or described as square or rectangular can have rounded or curved features, and regions shown as straight lines may have some irregularity. Thus, the regions illustrated in the figures are schematic and their shapes are not intended to illustrate the precise shape of a region of a device and are not intended to limit the scope of the disclosure. Additionally, sizes of structures or regions may be exaggerated relative to other structures or regions for illustrative purposes and, thus, are provided to illustrate the general structures of the present subject matter and may or may not be drawn to scale. Common elements between figures may be shown herein with common element numbers and may not be subsequently re-described.

The present disclosure relates to light-emitting diodes (LEDs), and more particularly, to lens formed by additive manufacturing for LED packages. Additive manufacturing is used to progressively cure precursor materials for lenses in directions away from corresponding submounts. Progressively curing precursor materials may be performed in a layer-by-layer manner or in a continuous manner. Such additive manufacturing allows complex lens shapes that form primary optics and encapsulation for LED chips of LED packages. Complex shapes include pockets of air or other materials embedded within lens materials, pockets formed about LED chips, progressively increasing lens widths, Fresnel shapes, and/or asymmetric shapes, among others.

Before delving into specific details of various aspects of the present disclosure, an overview of various elements that may be included in exemplary LED packages of the present disclosure is provided for context. An LED chip typically comprises an active LED structure or region that can have many different semiconductor layers arranged in different ways. The fabrication and operation of LEDs and their active structures are generally known in the art and are only briefly discussed herein. The layers of the active LED structure can be fabricated using known processes with a suitable process being fabrication using metal organic chemical vapor deposition. The layers of the active LED structure can comprise many different layers and generally comprise an active layer sandwiched between n-type and p-type oppositely doped epitaxial layers, all of which are formed successively on a growth substrate. It is understood that additional layers and elements can also be included in the active LED structure, including, but not limited to, buffer layers, nucleation layers, super lattice structures, undoped layers, cladding layers, contact layers, and current-spreading layers and light extraction layers and elements. The active layer can comprise a single quantum well, a multiple quantum well, a double heterostructure, or super lattice structures.

The active LED structure can be fabricated from different material systems, with some material systems being Group Ill nitride-based material systems. Other material systems include organic semiconductor materials, and Group Ill-V systems such as gallium phosphide (GaP), gallium arsenide (GaAs), indium phosphide (InP), and related compounds. Different embodiments of the active LED structure can emit different wavelengths of light depending on the material system.

In certain embodiments, the active LED structure emits blue light with a peak wavelength range in a range of 430 nanometers (nm) to 480 nm. In other embodiments, the active LED structure emits green light with a peak wavelength in a range of 500 nm to 570 nm. In other embodiments, the active LED structure emits orange and/or red light with a peak wavelength range of 600 nm to 700 nm. In still further embodiments, the active LED structure may emit cyan light with a peak wavelength in a range of 485 nm to 500 nm or violet light with a peak wavelength in a range from 400 nm to 420 nm. In certain embodiments, the active LED structure may be configured to emit light that is outside the visible spectrum, including one or more portions of the ultraviolet (UV) spectrum, the infrared (IR) or near-IR spectrum. The UV spectrum is typically divided into three wavelength range categories denotated with letters A, B, and C. In this manner, UV-A light is typically defined as a peak wavelength range from 315 nm to 400 nm, UV-B is typically defined as a peak wavelength range from 280 nm to 315 nm, and UV-C is typically defined as a peak wavelength range from 100 nm to 280 nm. UV LEDs are of particular interest for use in applications related to the disinfection of microorganisms in air, water, and surfaces, among others. In other applications, UV LEDs may also be provided with one or more lumiphoric materials to provide LED packages with aggregated emissions having a broad spectrum and improved color quality for visible light applications. Near-IR and/or IR wavelengths for LED structures of the present disclosure may have wavelengths above 700 nm, such as in a range from 700 nm to 1000 nm, or more.

As used herein, a layer or region of a light-emitting device may be considered to be “transparent” when at least 80% of emitted radiation that impinges on the layer or region emerges through the layer or region. Moreover, as used herein, a layer or region of an LED is considered to be “reflective” or embody a “mirror” or a “reflector” when at least 80% of the emitted radiation that impinges on the layer or region is reflected. In some embodiments, the emitted radiation comprises visible light such as blue and/or green LEDs with or without lumiphoric materials. In other embodiments, the emitted radiation may comprise nonvisible light. For example, in the context of GaN-based blue and/or green LEDs, silver (Ag) may be considered a reflective material (e.g., at least 80% reflective). In the case of UV LEDs, appropriate materials may be selected to provide a desired, and in some embodiments high, reflectivity and/or a desired, and in some embodiments low, absorption. In certain embodiments, a “light-transmissive” material may be configured to transmit at least 50% of emitted radiation of a desired wavelength.

The present disclosure is applicable for LED chips having a variety of geometries, such as vertical geometry or lateral geometry. A vertical geometry LED chip typically includes anode and cathode connections on opposing sides or faces of the LED chip. A lateral geometry LED chip typically includes both anode and cathode connections on the same side of the LED chip that is opposite a substrate, such as a growth substrate. In certain embodiments, a lateral geometry LED chip may be mounted on a submount of an LED package such that the anode and cathode connections are on a face of the LED chip that is opposite the submount. In this configuration, wirebonds may be used to provide electrical connections with the anode and cathode connections. In other embodiments, a lateral geometry LED chip may be flip-chip mounted on a surface of a submount of an LED package such that the anode and cathode connections are on a face of the active LED structure that is adjacent to the submount. In this configuration, electrical traces or patterns may be provided on the submount for providing electrical connections to the anode and cathode connections of the LED chip. In a flip-chip configuration, the active LED structure is configured between the substrate of the LED chip and the submount for the LED package. Accordingly, light emitted from the active LED structure may pass through the substrate in a desired emission direction. In other embodiments, an active LED structure may be bonded to a carrier submount, and the growth substrate may be removed such that light may exit the active LED structure without passing through the growth substrate.

LED packages may include one or more elements, such as lumiphoric materials and electrical contacts, among others, that are provided with one or more LED chips on a support member, such as a submount or a lead frame. Suitable materials for submounts include, but are not limited to, ceramic materials such as aluminum oxide or alumina, AlN, or organic insulators like polyimide (PI) and polyphthalamide (PPA). Submounts may also comprise a printed circuit board (PCB), sapphire, Si or any other suitable material. For PCB embodiments, different PCB types can be used such as standard FR-4 PCB, metal core PCB, or any other type of PCB. In still further embodiments, the support structure may embody a lead frame structure with a lead frame and a corresponding housing positioned about portions of the lead frame. Light-altering materials may be arranged within LED packages to reflect or otherwise redirect light from the one or more LED chips in a desired emission direction or pattern.

As used herein, “light-altering materials” may include many different materials including light-reflective materials that reflect or redirect light, that scatter light, light-absorbing materials that absorb light, lumiphoric materials, and materials that act as a thixotropic agent. As used herein, the term “light-reflective” refers to materials or particles that reflect, refract, scatter, or otherwise redirect light. For light-reflective materials, the light-altering material may include at least one of fused silica, fumed silica, titanium dioxide (TiO₂), or metal particles suspended in a binder, such as silicone or epoxy. In certain aspects, the particles may have an index or refraction that is configured to refract light emissions in a desired direction. In certain aspects, light-reflective particles may also be referred to as light-scattering particles. For light-absorbing materials, the light-altering material may include at least one of carbon, silicon, or metal particles suspended in a binder, such as silicone or epoxy. The light-reflective materials and the light-absorbing materials may comprise nanoparticles. In certain embodiments, the light-altering material may comprise a generally white color to reflect and redirect light. In other embodiments, the light-altering material may comprise a generally opaque color, such as black or gray for absorbing light and increasing contrast. In certain embodiments, the light-altering material includes both light-reflective material and light-absorbing material suspended in a binder.

Subject matter of the present disclosure relates to solid state light-emitting devices such as LED packages incorporating lens structures arranged over one or more solid state light emitters (e.g., LED chips), and related methods. Conventional primary optics in LED packages are typically formed by encapsulant materials for LED chips. LED chips may be effectively embedded within the encapsulant materials and corresponding shapes of the encapsulant materials are designed to provide desired emission profiles. Conventional techniques for forming primary optics include molding of materials, such as silicone, using mold blocks and the like on LED package submounts. Although there is some ability to change lens shapes by changing mold blocks, the types and shapes of lenses that are manufacturable are limited by the ability to remove mold blocks from the lenses without damaging or otherwise changing the lens shape. Certain aspects of the present disclosure relate to LED packages with integrated lens structures fabricated and manufactured using additive techniques, such as three-dimensional (3D) printing technologies, among others. In this regard, more complex structures for primary optics for LED packages may be realized. Certain aspects relate to processes where precursor materials are used to additively manufacture primary optics that are integrated within LED packages.

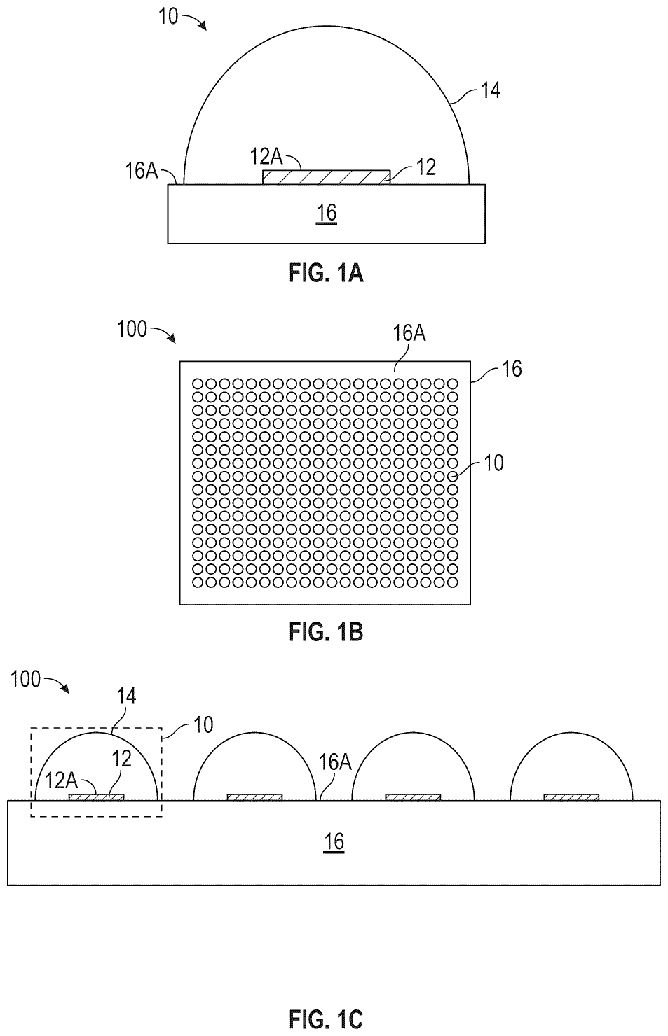

FIG. 1A shows a simplified cross-sectional view of an exemplary LED package 10 with an LED chip 12 encapsulated by a lens 14 that forms an integrated primary optic. The LED chip 12 is supported and/or mounted on a submount 16, and a top surface 12A of the LED chip 12 is positioned to emit light toward the lens 14. According to various embodiments, the submount 16 may be singulated from a larger panel or a subassembly used for bulk manufacturing. As illustrated, the lens 14 forms a unitary structure that is disposed on a top surface 16A of the submount 16 to effectively encapsulate the LED chip 12. Emissions from the LED chip 12 are generally emitted or reflected in a direction away from the top surface 16A to exit the lens 14 in a desired emission profile.

FIG. 1B shows a top view of an LED panel 100 having a plurality of the LED packages 10 from FIG. 1 formed over a top surface 16A of a panel or submount 16 according to aspects of the present disclosure. In FIG. 1B, the submount 16 forms a portion of the larger LED panel 100 and portions of which will be singulated to form the LED package 10 of FIG. 1A.

FIG. 1C illustrates a cross-sectional view of a portion of the LED panel 100 of FIG. 1B having a plurality of the LED packages 10 fabricated according to aspects of the present disclosure. As previously described in reference to FIG. 1B, the LED panel 100 includes the submount 16 having the top surface 16A. The LED chips 12 are disposed over the top surface 16A and a single LED chip 12 or a combination of multiple LED chips 12 are encapsulated by one or more lenses 14.

In this regard, FIGS. 1A to 1C are provided to facilitate description of various structures and fabrication processes of lenses, LED packages, and LED panels utilizing additive manufacturing as described herein. The lenses 14, the LED packages 10, and the LED panels 100, as shown and described in FIGS. 1A to 1C, are provided as exemplary structures. The various embodiments of the present disclosure are applicable to any size, shape, number, type, location, orientation, and so forth of lenses, LED packages, and corresponding LED panels.

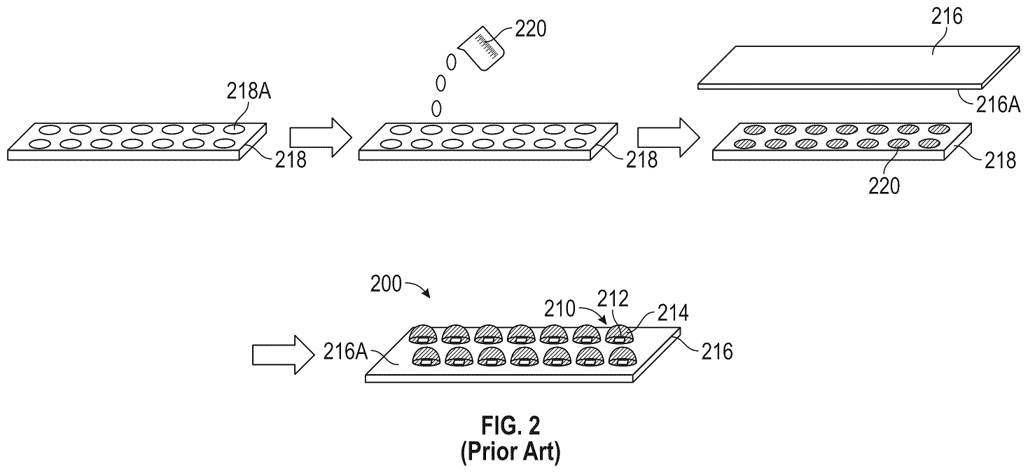

FIG. 2 shows a conventional molding method for fabrication of lenses 214 and LED packages 210 of an LED panel 200. Referring to FIG. 2, generally, a plurality of casting molds 218A of a mold block 218 are filled with a curable resin precursor solution 220 (hereinafter referred to as the precursor solution 220) that may be, for example, a curable silicone solution. Next, a top surface 216A of a submount 216 of the LED panel 200 is positioned over the mold block 218. The top surface 216A is then brought into contact with the mold block 218 such that LED chips 212 on the top surface 216A are positioned in respective casting molds 218A that are now filled with the precursor solution 220. After curing, the mold block 218 is released, resulting in the LED panel 200 with LED chips 212 encapsulated within the lenses 214. Care should be taken to reduce damage to the lenses 214 as they are released from the casting molds 218A. Moreover, the structure and shape of the lenses 214 may be limited by certain shapes required to release the lenses 214 from the casting molds 218A. For example, lenses with complex geometries may be difficult to achieve using conventional molding methods.

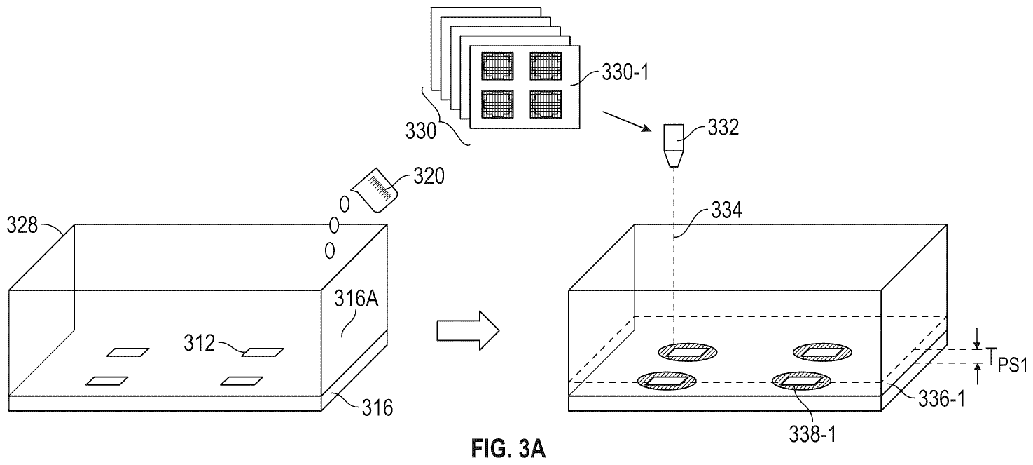

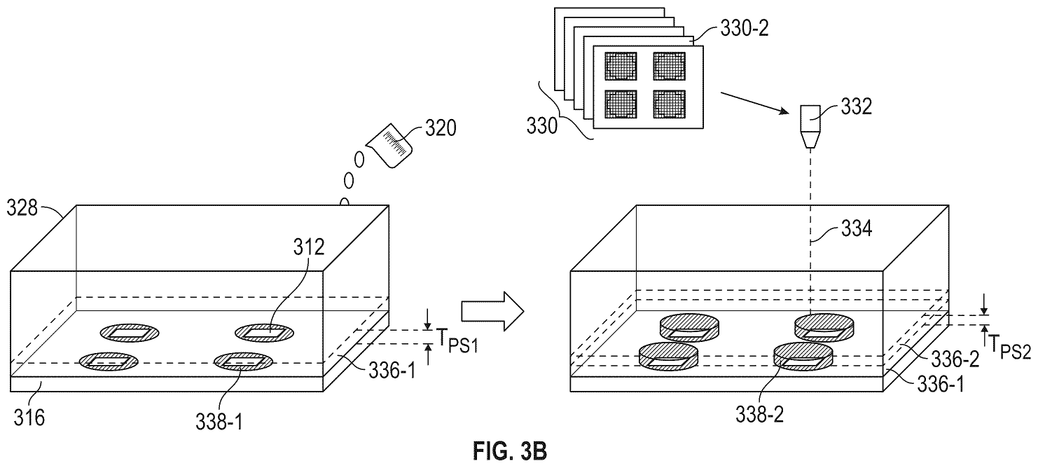

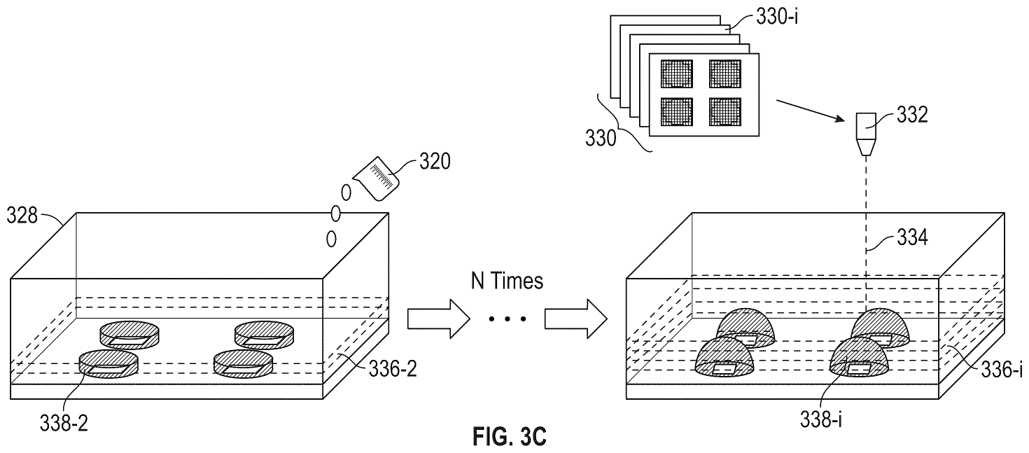

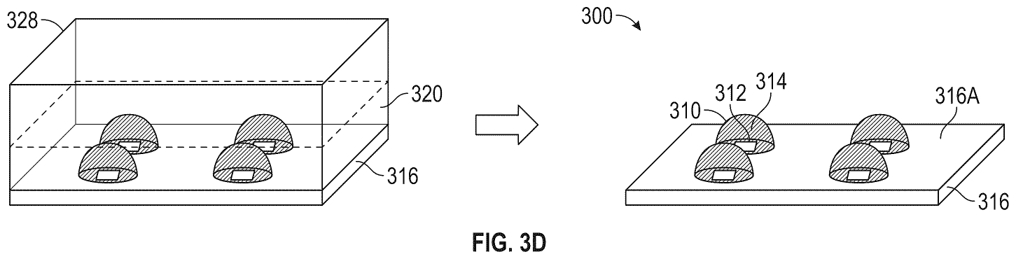

FIGS. 3A to 3D illustrate various steps of a layer-by-layer additive printing method according to principles of the present disclosure for fabrication of lenses 314 on LED chips 312 for LED packages 310 of a corresponding LED panel 300. As will be discussed in more details herein, the layer-by-layer additive printing method may include rastering of a focused UV beam 334 generated by a UV laser device 332 over a UV-curable resin precursor solution 320 (hereinafter referred to as the precursor solution 320), to selectively cure predetermined areas of the precursor solution 320, in a successive and layer-by-layer manner, and in accordance with corresponding ones of raster graphics 330.

FIG. 3A shows a submount 316, or submount panel, after formation of a first cured layer of lenses 338-1 using the layer-by-layer additive printing method. FIG. 3A generally illustrates a fabrication step for placing the submount 316 in a resin tank 328, providing the precursor solution 320 to the resin tank 328 to uniformly cover a top surface 316A of the submount 316 with a first precursor solution layer 336-1, and rastering the focused UV beam 334 in accordance with a first raster graphic 330-1 to cure predetermined areas of the precursor solution 320 and form the first cured layer of lenses 338-1. As illustrated, once the precursor solution 320 is added to the resin tank 328, the first precursor solution layer 336-1 forms above the top surface 316A of the submount 316 with a first thickness T_{PS1}. The precursor solution 320 may be a UV-curable silicone solution, acrylates, epoxies, or the like. Next, the UV laser device 332 generates the focused UV beam 334 and illuminates predetermined areas of the first precursor solution layer 336-1 as specified by the first raster graphic 330-1 to form the first cured layer of lenses 338-1. The first raster graphic 330-1 may be a matrix of pixels that provides a two-dimensional (2D) map of the areas of the first precursor solution layer 336-1 that is to be illuminated and cured over the top surface 316A of the submount 316 to form the first cured layer of lenses 338-1, at least partially, over and above each of the LED chips 312 of the submount 316.

Upon formation of the first cured layer of lenses 338-1, the submount 316 may optionally be removed from the resin tank 328 and followed by one or more optional post processing procedures to improve clarity, structural integrity, uniformity, mechanical characteristics, and/or other characteristics of the first cured layer of lenses 338-1. In this regard, the one or more post processing procedures may include a high temperature treatment, a high-pressure treatment, a vacuum drying, a freeze drying, a UV illumination, a surface treatment, or the like.

FIG. 3B illustrates the submount 316 as seen after a formation of a second cured layer of lenses 338-2 using the layer-by-layer additive printing method. FIG. 3B generally illustrates a subsequent fabrication step for utilizing the focused UV beam 334 to illuminate predetermined areas of a second precursor solution layer 336-2 to cure and form a second cured layer of lenses 338-2.

After completion of the fabrication step illustrated in FIG. 3A, an additional amount of the precursor solution 320 is added to the resin tank 328 to form the second precursor solution layer 336-2 above top surfaces of the first cured layer of lenses 338-1. In application, the precursor solution 320 corresponding to the first precursor solution layer 336-1 and the second precursor solution layer 336-2 mix with one another and therefore are indistinguishable. In this regard, the first precursor solution layer 336-1 and the second precursor solution layer 336-2 may be differentiated from one another based on an imaginary plane parallel to and above the top surface 316A of the submount 316. In this regard, a first imaginary plane may form above the top surface 316A of the submount 316 having a height corresponding to the first thickness T_{PS1} of the first precursor solution layer 336-1. Furthermore, a second imaginary plane may form above the top surface of the first precursor solution layer 336-1 having a height corresponding to a second thickness T_{PS2} of the second precursor solution layer 336-2.

Upon formation of the second precursor solution layer 336-2, the focused UV beam 334 generated by the UV laser device 332 is utilized to expose predetermined areas of the second precursor solution layer 336-2 in accordance with a second raster graphic 330-2 such that the second cured layer of lenses 338-2 forms, at least partially, over, around, and/or above the first cured layer of lenses 338-1.

In certain embodiments, the focused UV beam 334 may further extend into the first precursor solution layer 336-1 to expose and cure predetermined areas that are adjacent to the first precursor solution layer 336-1 and the second precursor solution layer 336-2. In this manner, an interlocking solid structure may form between adjacent and connecting layers, such as the first cured layer of lenses 338-1 and the second cured layer of lenses 338-2, that form part of lenses 314. This is particularly advantageous as it further enhances the unity, clarity and quality of the lenses 314 that are fabricated using the layer-by-layer additive printing method.

FIG. 3C illustrates the submount 316 as seen after repeating the steps of FIG. 3B a selected number N of times to fabricate lenses 314 using the layer-by-layer additive printing method. In this regard, FIG. 3C generally illustrates a subsequent fabrication step for repeating the fabrication step of FIG. 3B a selected number N of times to fabricate the LED panel 300 with the lenses 314.

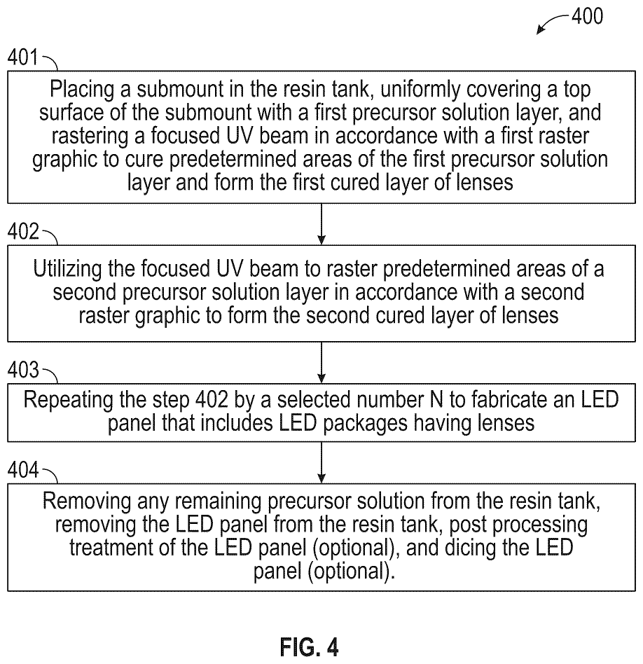

In this manner, additional amounts of the precursor solution 320 are added to the resin tank 328 to provide an i^{th} precursor solution layer 336-i (where i is a number and 2<i≤N). Next, the focused UV beam 334 is used to expose predetermined areas of the i^{th} precursor solution layer 336-i in accordance with an i^{th} raster graphic 330-i. In this manner, an i^{th} cured layer of lenses 338-i is formed, at least partially, over, around, and/or above a preceding cured layer of lenses. Once the procedure as outlined in FIG. 3B (or step 402 of FIG. 4) is repeated for N times, the lenses 314 encapsulating the LED chips 312 form over the top surface 316A of the submount 316. In this manner, the LED packages 310 that form part of the LED panel 300 are fabricated.

FIG. 3D illustrates the LED panel 300 having a plurality of LED packages 310 as manufactured using the layer-by-layer additive printing method and as seen after being removed from the resin tank 328. In this regard, FIG. 3D corresponds with a fabrication step (404 of FIG. 4) for removing any remaining precursor solution 320 from the resin tank 328, removing the LED panel 300 from the resin tank 328, and any optional post processing treatment of the LED panel 300. A singulation or dicing step may then be implemented to separate individual ones of the LED packages 310 from the LED panel 300.

FIG. 4 illustrates an exemplary process flow diagram 400 describing the general fabrication steps of the layer-by-layer additive printing method of FIGS. 3A to 3D. In FIG. 4, step 401 generally corresponds with FIG. 3A for placing the submount 316 in a resin tank 328, providing the precursor solution 320 to the resin tank 328 to uniformly cover the top surface 316A of the submount 316 with the first precursor solution layer 336-1, and rastering the focused UV beam 334 in accordance with the first raster graphic 330-1 to cure predetermined areas of the precursor solution 320 and form the first cured layer of lenses 338-1. Step 402 generally corresponds with FIG. 3B for utilizing the focused UV beam 334 to illuminate predetermined areas of the second precursor solution layer 336-2 to cure and form the second cured layer of lenses 338-2. Step 402 generally corresponds with FIG. 3C for repeating the step 402 a selected number N of times to fabricate the LED panel 300 with the lenses 314. Step 404 generally corresponds with FIG. 3D for removing any remaining precursor solution 320 from the resin tank 328, removing the LED panel 300 from the resin tank 328, and any optional post processing treatment of the LED panel 300.

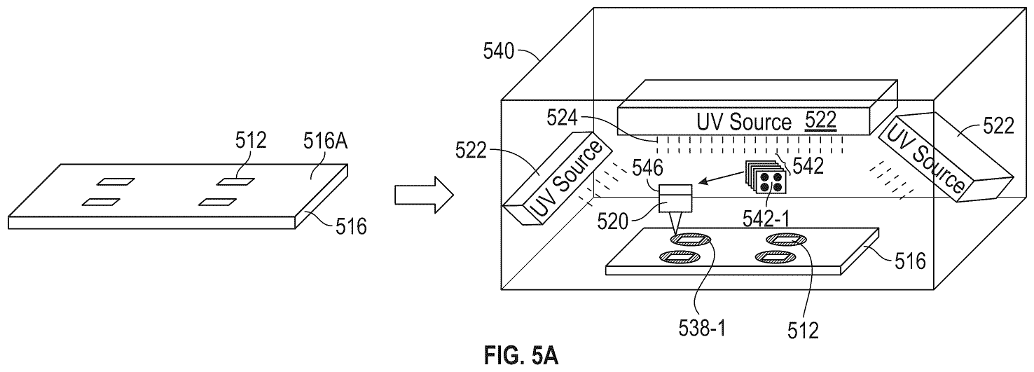

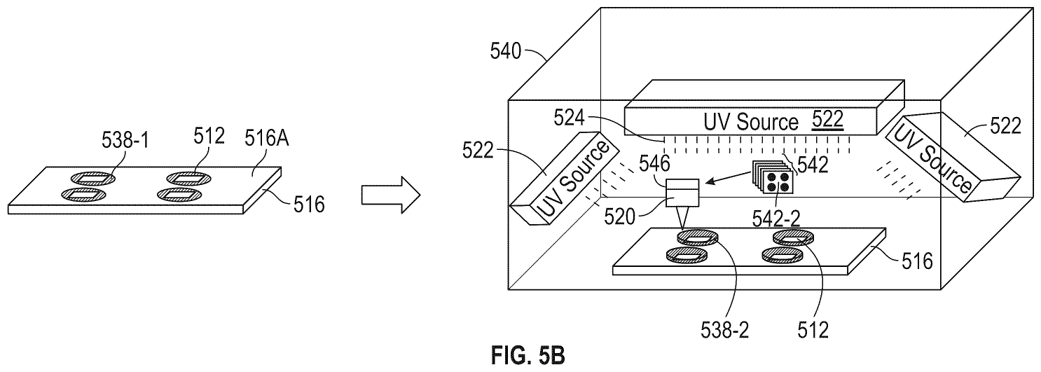

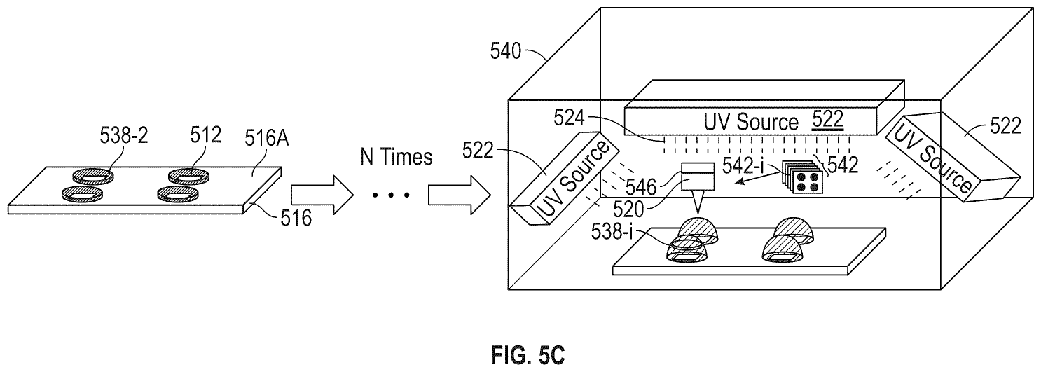

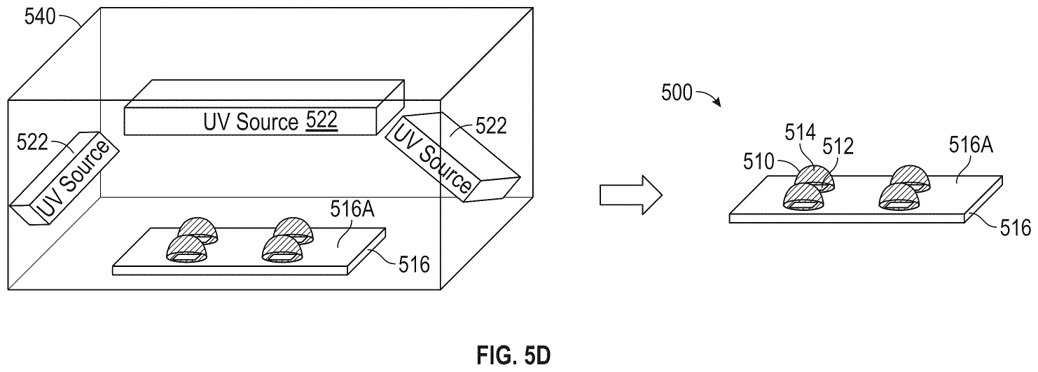

FIGS. 5A to 5D describe an injection printing method used to fabricate lenses 514 and LED packages 510 for an LED panel 500. As will be discussed in more details herein, the injection printing method includes using an extrusion nozzle 546 to extrude and deposit a precursor solution 520 at a controlled pace and a pre-determined output rate over a top surface 516A of a submount 516. In this regard, the submount 516 having one or more LED chips 512 is first placed within a UV chamber 540 and the precursor solution 520 is then deposited, in a successive manner, over predetermined areas as indicated by corresponding ones of layer layouts 542. The precursor solution 520 is cured by UV light 524 that is generated by the UV sources 522 of the UV chamber 540 as it is deposited over, around, and above the LED chips 512 of the submount 516, forming a plurality of lenses 514, and therefore, LED packages 510, as part of the LED panel 500. While FIGS. 5A to 5D are provided in the context forming an array of the lenses 514, the principles described are also applicable to forming one lens 514 at a time.

FIG. 5A shows the submount 516 at a fabrication step after a first cured layer of lenses 538-1 is formed using the injection printing method. In this regard, FIG. 5A generally illustrates placing the submount 516 in the UV chamber 540 and introducing the precursor solution 520 over selected portions of the top surface 516A of the submount 516 using the extrusion nozzle 546 such that the precursor solution 520 is cured by the UV light 524 to form the first cured layer of lenses 538-1.

The UV chamber 540 is configured to expose areas over and above the top surface 516A of the submount 516 with the UV light 524 generated by one or more UV sources 522. In certain embodiments, the UV chamber 540 provides a broad angular distribution of the UV light 524 by employing multiple UV sources 522 and/or reflectors (not shown). In this manner, the UV light 524 is exposed in a substantially uniform manner over and above the top surface 516A of the submount 516.

The extrusion nozzle 546 moves above the top surface 516A of submount 516 to extrude the precursor solution 520 over predetermined areas of the top surface 516A in accordance with a first layer layout 542-1 of the layer layouts 542. In this regard, the first layer layout 542-1 provides a 2D graphic map of a shape and structure of the first cured layer of lenses 538-1. The extrusion nozzle 546 deposits the precursor solution 520 at a rate over the top surface 516A of submount 516 such that the precursor solution 520 is cured by the UV light 524 upon and after it is deposited. In this manner, the UV chamber 540 and the UV light 524 therein are utilized to form the first cured layer of lenses 538-1 that forms over the top surface 516A of the submount 516 and at least partially covers the LED chips 512.

Upon formation of the first cured layer of lenses 538-1, the submount 516 may be removed from the UV chamber 540 followed by one or more optional post processing procedures (not shown) to improve clarity, structural integrity, uniformity, or other optical or mechanical characteristics of the first cured layer of lenses 538-1 as it forms part of the lenses 514 of the LEDs 510. In this regard, the post processing procedures may include one or more of a high temperature treatment, a high-pressure treatment, a vacuum drying, a freeze drying, a UV illumination, a surface treatment, or the like. Upon completion of the post processing procedures, the submount 516 is placed back into the UV chamber 540 for further processing.

FIG. 5B illustrates the submount 516 as seen after formation of a second cured layer of lenses 538-2 using the injection printing method. In this regard, FIG. 5B corresponds with using the extrusion nozzle 546 to introduce the precursor solution 520, at least partially, over, around, and above the first cured layer of lenses 538-1 such the precursor solution 520 is cured by the UV light 524 to form the second cured layer of lenses 538-2.

In this regard, the extrusion nozzle 546 is utilized to deposit the precursor solution 520 over, around, and above the first cured layer of lenses 538-1 in accordance with a second layer layout 542-2. The precursor solution 520 is cured by the UV light 524 generated by the UV sources 522 to form the second cured layer of lenses 538-2. In certain embodiments, the first cured layer of lenses 538-1 and the second cured layer of lenses 538-2 form interlocking and unitary structures that become parts of the lenses 514 of the LED packages 510.

FIG. 5C illustrates the submount 516 as seen after repeating the steps as disclosed in FIG. 5B a selected number N of times to fabricate lenses 514 using the injection printing method. In this regard, FIG. 5C illustrates a fabrication step for repeating the fabrication step of FIG. 5B a selected number N of times to fabricate lenses 514 that form part of LED packages 510 for the LED panel 500.

Upon formation of the second cured layer of lenses 538-2, the extrusion nozzle 546 is utilized to deposit and extrude the precursor solution 520 in a manner as described in reference to FIG. 5B and in accordance with an i^{th} layer layout 542-i such that the precursor solution 520 is cured by the UV light 524 to form the i^{th} cured layer of lenses 538-i. In this manner, lenses 514 of the LED packages 510 for the LED panel 500 are formed to desired shapes.

FIG. 5D shows the LED panel 500 having a plurality of lenses 514 as part of the LED packages 510 as manufactured using the injection printing method and as seen after being removed from the UV chamber 540. In this regard, FIG. 5D corresponds with a fabrication step for removing the LED panel 500 from the UV chamber 540 followed by optional post processing treatment of the lenses 514.

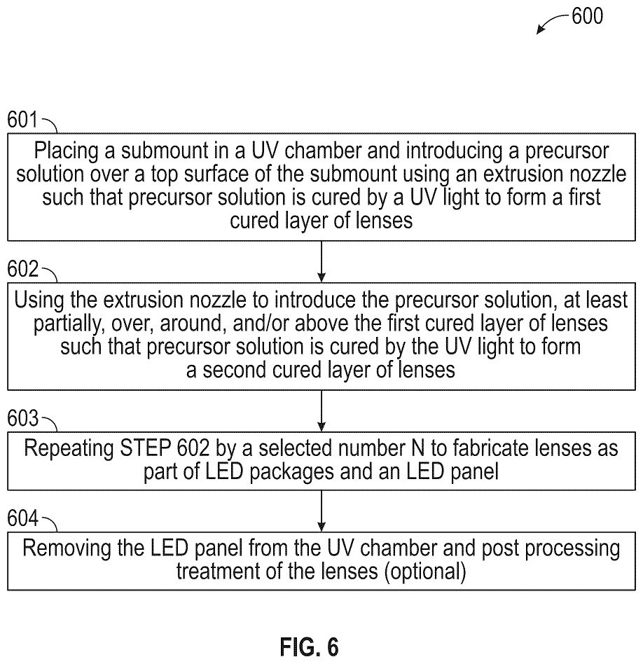

FIG. 6 illustrates an exemplary process flow diagram 600 describing the general fabrication steps of the injection printing method of FIGS. 5A to 5D. In FIG. 6, step 601 generally corresponds with FIG. 5A for placing the submount 516 in the UV chamber 540 and introducing the precursor solution 520 over the top surface 516A of the submount 516 using the extrusion nozzle 546 and in accordance with the first layer layout 542-1 such the precursor solution 520 is cured by the UV light 524 to form the first cured layer of lenses 538-1. Step 602 generally corresponds with FIG. 5B for using the extrusion nozzle 546 to deposit the precursor solution 520, at least partially, over, around, and above the first cured layer of lenses 538-1, within the UV chamber 540 and in accordance with the second layer layout 542-2, such that the precursor solution 520 is cured by the UV light 542 to form the second cured layer of lenses 538-2. Step 603 generally corresponds with FIG. 5C for repeating the step 602 by a selected number N to fabricate the LED panel 500 that includes the LED packages 510 having the lenses 514. Step 604 generally corresponds with FIG. 5D for removing the LED panel 500 from the UV chamber 540 followed by optional post processing treatment of the lenses 514.

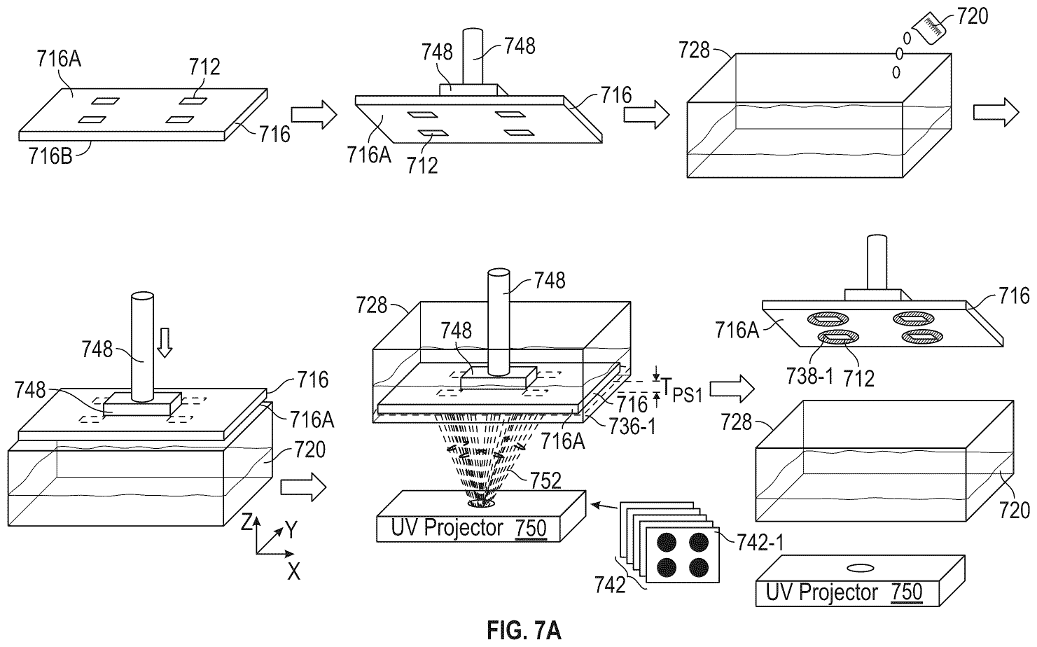

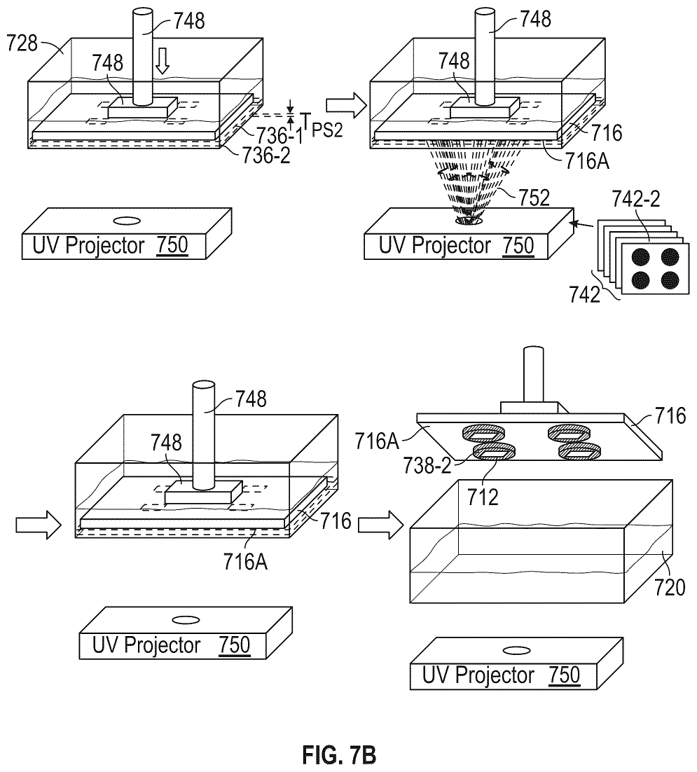

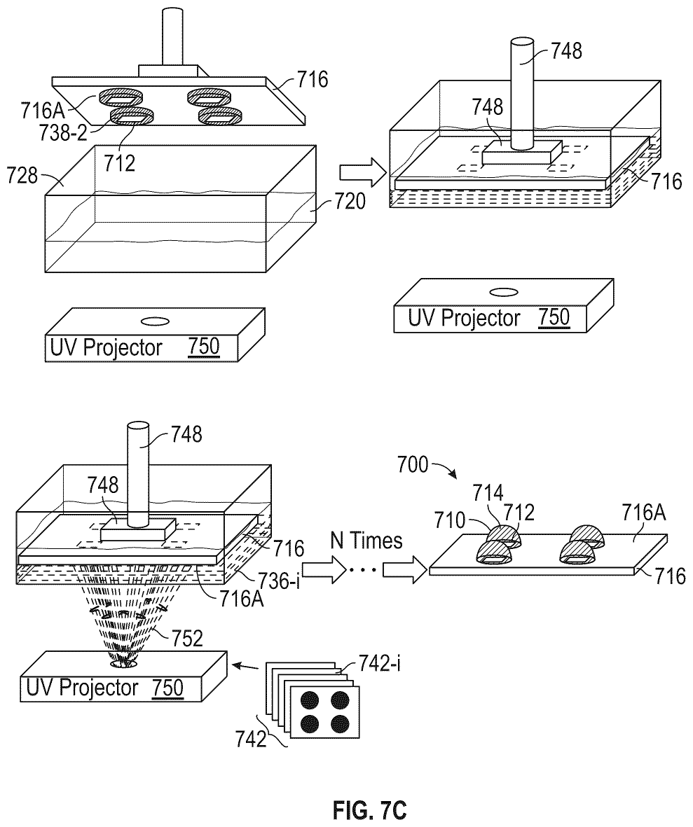

FIGS. 7A to 7C illustrate an additive digital light processing (DLP) method to fabricate lenses 714 and corresponding LED packages 710 of an LED panel 700. As will be discussed in more detail herein, a resin tank 728 contains a precursor solution 720 and a bottom surface of the resin tank 728 is transparent. Furthermore, a submount 716 is submerged in the precursor solution 720 within the resin tank 728 and is kept above the bottom surface of the resin tank 728 with the top surface 716A of the submount 716 facing downwards and towards the bottom surface of the resin tank 728. In this manner, the additive DLP method utilizes a UV projector 750, or the like, to project patterned UV light 752 corresponding to layer layouts 742 onto and through the bottom surface of the resin tank 728 to cure the precursor solution 720 in a continuous manner as the submount 716 is moved incrementally upward within the precursor solution 720. Accordingly, the lenses 714 of the LED packages 710 for the LED panel 700 are formed.

FIG. 7A shows the submount 716 after a first cured layer of lenses 738-1 is fabricated during the additive DLP method. In this regard, FIG. 7A corresponds with a fabrication step for providing the precursor solution 720 to the resin tank 728 having a bottom surface that is transparent, utilizing a stage 748 to hold and move the submount 716 along the Z-axis and within the resin tank 728 with the top surface 716A of the submount 716 facing the bottom surface of the resin tank 728, lowering the submount 716 within the resin tank 728 such that a first precursor solution layer 736-1 having a predetermined thickness T_{PS1} remains between the top surface 716A of the submount 716 and the bottom surface of the resin tank 728, using a UV projector 750 to radiate the first precursor solution layer 736-1 through the bottom surface of the resin tank 728 with the UV light 752 having a pattern corresponding to the first layer layout 742-1. In this manner, a first cured layer of lenses 738-1 is cured and formed over the top surface 716A of the submount 716 and the first cured layer of lenses 738-1 forms part of the lenses 714 for the LED packages 710. For illustrative purposes, the submount 716 is shown removed from the resin tank 728 to show the first cured layer of lenses 738-1. In practice, the submount 716 may or may not be removed from the resin tank 728 before additional cured layers are formed.

The UV projector 750 may be able to directly generate a UV light 752 having a pattern that corresponds to each of the layer layouts 742. Alternatively or in addition, patterned masks, a digital micromirror device, or other suitable methods or devices may be used to generate the UV light 752 having a pattern that corresponds to each of the layer layouts 742.

FIG. 7B illustrates the submount 716 of FIG. 7A after formation of a second cured layer of lenses 738-2 as part of a subsequent fabrication step of the additive DLP method. In this regard, FIG. 7B corresponds with utilizing the stage 748 to elevate the submount 716 within the resin tank 728 such that a second precursor solution layer 736-2 remains between top surfaces of the first cured layer of lenses 738-1 and the bottom surface of the resin tank 728, and using the UV projector 750 to radiate the second precursor solution layer 736-2 through the bottom surface of the resin tank 728 with the UV light 752 having a pattern corresponding to a second layer layout 742-2 such that the second cured layer of lenses 738-2 is cured and formed over and around the first cured layer of lenses 738-1. This is particularly advantageous as it provides a continuous formation of lenses 714 that also encapsulate LED chips 712. In certain embodiments, the UV light 752 having a pattern corresponding to the second layer layout 742-2 may expose areas above the second precursor solution layer 736-2 to cure predetermined areas surrounding the first cured layer of lenses 738-1 in order to further interlock adjacent cured layers and enhance the unity, clarity and quality of the resulting lenses 714. As with FIG. 7A, the submount 716 is shown removed from the resin tank 728 in FIG. 7B to show the second cured layer of lenses 738-2. In practice, the submount 716 may or may not be removed from the resin tank 728 before additional cured layers are formed.

FIG. 7C illustrates repeating the fabrication step of FIG. 7B a selected number N of times to complete fabrication of the lenses 714. In FIG. 7C, the submount 716 is initially shown removed from the resin tank 728 for illustrative purposes. As mentioned above, the submount 716 may or may not remain in the resin tank 728 throughout the formation of the lenses 714, depending on the embodiment. In certain embodiments, the stage 748 is utilized to elevate the submount 716 within the resin tank 728 such that an i^{th} precursor solution layer 736-i (where i is a number and 2<i≤N) remains over the bottom surface of the resin tank 728. In this regard, the continuous elevation of the submount 716, and therefore, the top surface 716A of the submount 716 is followed by exposure of the UV light 752 having a pattern corresponding to the i^{th} layer layout 742-i such that each successive cured layer of lenses is cured to form the shape of the resulting lenses 714.

According to other embodiments, the fabrication of lenses 714 using the additive DLP method may constitute a continuous curing of the precursor solution 720 under the top surface 716A of the submount 716 as the stage 748 continually elevates the submount 716 within the resin tank 728, along the Z-axis, and in a direction away from the bottom surface of the resin tank 728. In this manner, the UV light 752 is continually adjusted to patterns corresponding to the layer layouts 742 along the Z-axis.

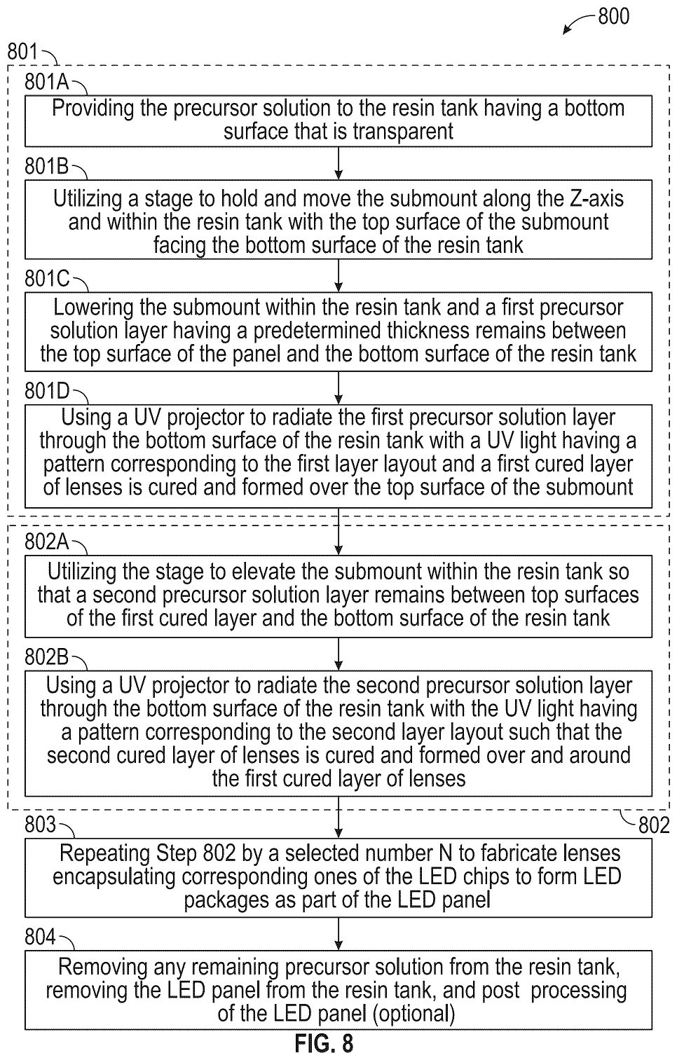

FIG. 8 illustrates an exemplary process flow diagram 800 describing the general fabrication steps of the additive DLP method of FIGS. 7A to 7C. In FIG. 8, step 801, subdivided as sub-steps 801A to 801D, generally corresponds with FIG. 7A. Sub-step 801A corresponds with providing the precursor solution 720 to the resin tank 728. Sub-step 801B corresponds with utilizing the stage 748 to hold and move the submount 716 along the Z-axis within the resin tank 748 with the top surface 716A of the submount 716 facing the bottom surface of the resin tank 728. Sub-step 801C corresponds with lowering the submount 716 within the resin tank 728 such that a first precursor solution layer 736-1 having a predetermined thickness T_{PS1} remains between the top surface 716A of the submount 716 and the bottom surface of the resin tank 18. Sub-step 801D corresponds with using the UV projector 750 to radiate the first precursor solution layer 736-1 through the bottom surface of the resin tank 728 with the UV light 752 having a pattern corresponding to the first layer layout 742-1 so that a first cured layer of lenses 738-1 is cured and formed over the top surface 716A of the submount 716.

Step 802, subdivided as sub-steps 802A to 802B, generally corresponds with FIG. 7B. Sub-step 802A corresponds with utilizing the stage 748 to elevate the submount 716 within the resin tank 728 such that a second precursor solution layer 736-2 remains between top surfaces of the first cured layer of lenses 738-1 and the bottom surface of the resin tank 728. Sub-step 802B corresponds with using the UV projector 750 to radiate the second precursor solution layer 736-2 through the bottom surface of the resin 728 with the UV light 752 having a pattern corresponding to the second layer layout 742-2 such that the second cured layer of lenses 738-2 is cured and formed over and around the first cured layer of lenses 738-1.

Steps 803 and 804 correspond with FIG. 7C. Step 803 corresponds with repeating the step 802 a selected number N of times to fabricate lenses 714 encapsulating corresponding ones of the LED chips 712 to form LED packages 714 as part of the LED panel 700. Step 804 describes removing any remaining precursor solution 720 from the resin tank 728, removing the LED panel 700 from the resin tank 728, and performing any optional post processing of the LED panel 700 as illustrated in FIG. 7C.

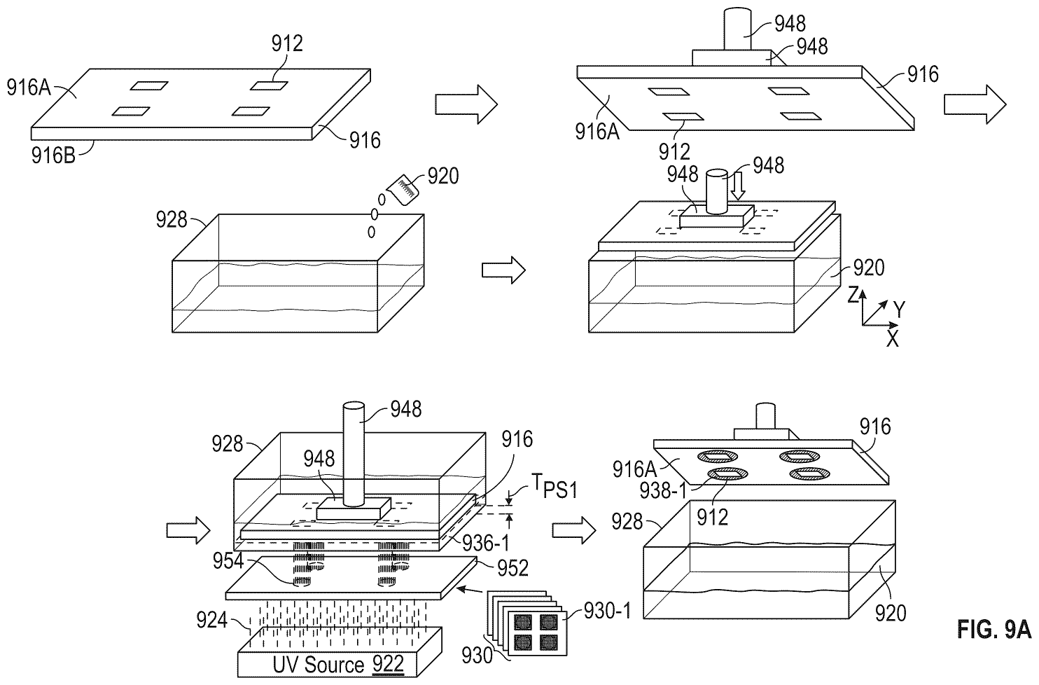

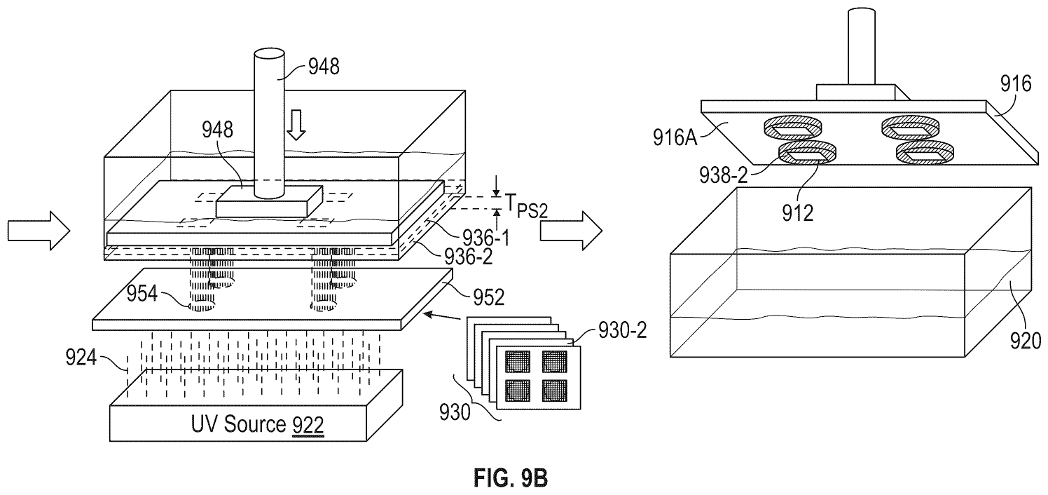

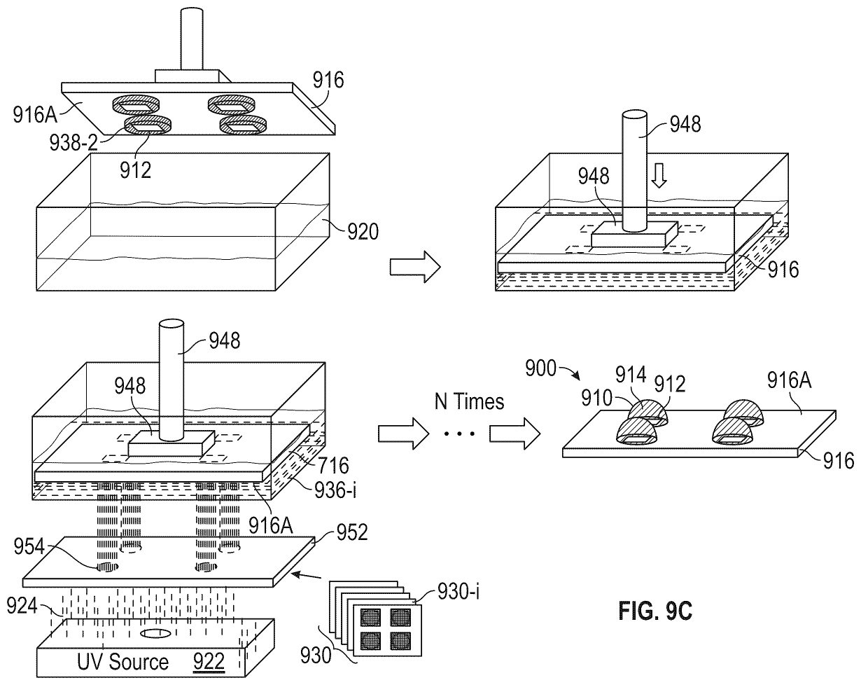

FIGS. 9A to 9C describe an additive liquid crystal display (LCD) printing method to fabricate lenses 914 and corresponding LED packages 910 of an LED panel 900. The additive LCD printing method is substantially similar to the DLP method as previously discussed in reference to FIGS. 7A to 7C and FIG. 8 with the exception that instead of using the UV projector 750, a UV light source or array 922 is used in conjunction with a liquid crystal to form LCD-based illumination. In this manner, patterned screens 930 are positioned to act as masks, revealing only the pixels associated with raster graphics needed to cure and form corresponding ones of LCD cured layers 938.

FIG. 9A shows a submount 916 with LED chips 912 positioned for formation of lenses by the LCD printing method according to aspects of the present disclosure. As illustrated, the UV light array 922 in conjunction with patterned screens 930 in creating UV light patterns 954 are utilized in a successive, sequential, and additive manner. The bottom surface of a resin tank 928 is transparent and enables the UV light patterns 954 to expose and cure a first precursor solution layer 936-1 of a precursor solution 920 within the resin tank 928 and under a top surface 916A of the submount 916. The submount 916 is moved by a stage 948 along the Z-axis so that the precursor solution 920 is cured in a continuous manner using the UV light patterns 954 to form a first LCD cured layer 938-1. In this manner, continuous and unified lenses 914 form over predetermined areas of the top surface 916A of the submount 916. The UV light pattern 954 is defined by a first patterned screen 930-1. For illustrative purposes, the submount 916 is shown removed from the resin tank 928 to show the first LCD cured layer 938-1. In practice, the submount 916 may or may not be removed from the resin tank 928 before additional LCD cured layers are formed.

FIG. 9B illustrates the submount 916 after formation of a second LCD cured layer 938-2 as part of a subsequent fabrication step of the additive LCD printing method. In this regard, FIG. 9B corresponds with utilizing the stage 948 to elevate the submount 916 within the resin tank 928 such that a second precursor solution layer 936-2 remains and using the UV light patterns 954 by way of a second patterned screen 930-2 to form the second LCD cured layer 938-2. As with FIG. 9A, the submount 916 is shown removed from the resin tank 928 in FIG. 9B to show the second LCD cured layer 938-2. In practice, the submount 916 may or may not be removed from the resin tank 928 before additional LCD cured layers are formed.

FIG. 9C illustrates repeating the fabrication step of FIG. 9B a selected number N of times to complete fabrication of the lenses 914. In FIG. 9C, the submount 916 is initially shown removed from the resin tank 928 for illustrative purposes. As mentioned above, the submount 916 may or may not remain in the resin tank 928 throughout the formation of the lenses 914, depending on the embodiment. The stage 948 is utilized to elevate the submount 916 within the resin tank 928 such that an ith precursor solution layer 936-i (where i is a number and 2<i≤N) remains over the bottom surface of the resin tank 928. In this regard, the continuous elevation of the submount 916 and, therefore, the top surface 916A of the submount 916 is followed by exposure of the UV light patterns 924 by way of the patterned screens 930-i such that each successive LCD cured layer 938-i completes formation of the shape of the resulting lenses 914. FIG. 9C further illustrates the LED panel 900 having the plurality of LED packages 910 after removing any remaining precursor solution 920 from the resin tank 928 and removing the LED panel 900 from the resin tank 928. Any optional post processing treatment of the LED panel 900 may also be performed.

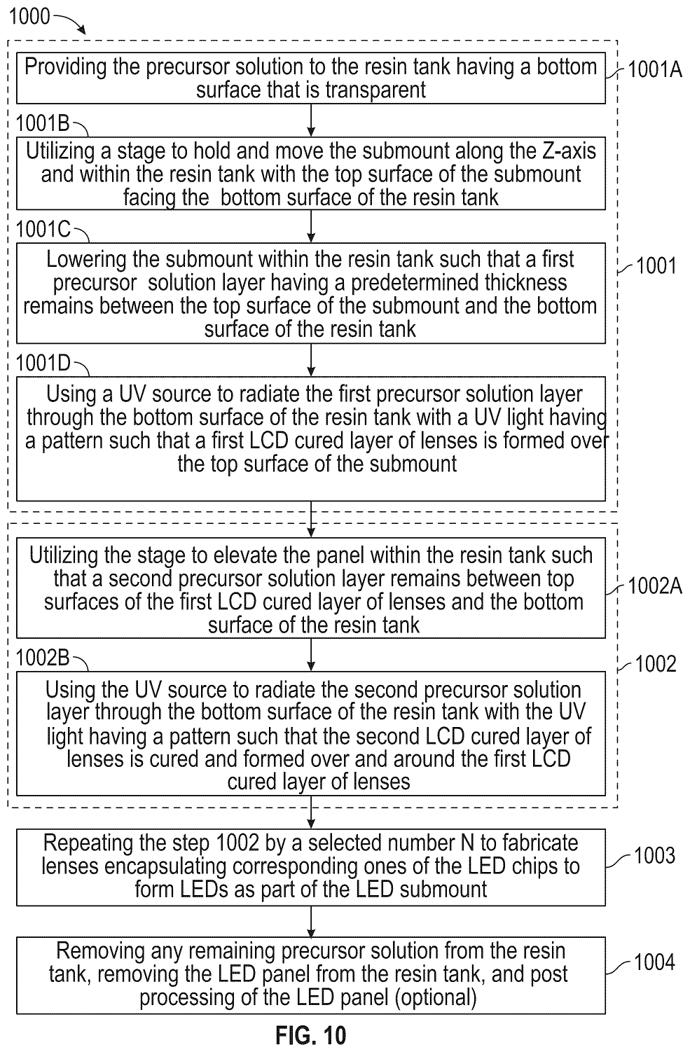

FIG. 10 illustrates an exemplary process flow diagram 1000 describing the general fabrication steps of the LCD printing method of FIGS. 9A to 9C. In FIG. 10, step 1001, subdivided as sub-steps 1001A to 1001D, generally corresponds with FIG. 9A. Sub-step 1001A corresponds with placing the precursor solution 920 into the resin tank 928 having a transparent bottom surface. Sub-step 1001B corresponds with utilizing the stage 948 to hold and move the submount 916 along the Z-axis and within the resin tank 928 with the top surface 916A of the submount 916 facing the bottom surface of the resin tank 928. Sub-step 1001C corresponds with lowering the submount 916 within the resin tank 928 such that a first precursor solution layer 936-1 having a predetermined thickness remains between the top surface 916A of the submount 916 and the bottom surface of the resin tank 928. Sub-step 1001D corresponds with using the UV source 922 to radiate the first precursor solution layer 936-1 through the bottom surface of the resin tank 928 with UV light 924 having a pattern (e.g., 954) corresponding to the first patterned screen 930-1 such that a first LCD cured layer 938-1 of lenses is cured and formed over the top surface 916A of the submount 916. Step 1002, subdivided as sub-steps 1002A and 1002B, generally correspond with FIG. 9B. Sub-step 1002A corresponds with utilizing the stage 948 to elevate the submount 916 within the resin tank 928 such that a second precursor solution layer 936-2 remains between top surfaces of the first LCD cured layer 938-1 and the bottom surface of the resin tank 928. Sub-step 1002B corresponds with using the UV source 922 to radiate the second precursor solution layer 936-2 through the bottom surface of the resin tank 928 with the UV light 924 having a pattern (e.g., 954) corresponding to the second patterned screen 930-2 such that the second LCD cured layer 938-2 is cured and formed over and around the first LCD cured layer 938-1. Step 1003 for repeating the step 1002 a selected number N of times and step 1004 for removing the LED panel 900 from the resin tank 928 and any post processing generally corresponds with FIG. 9C.

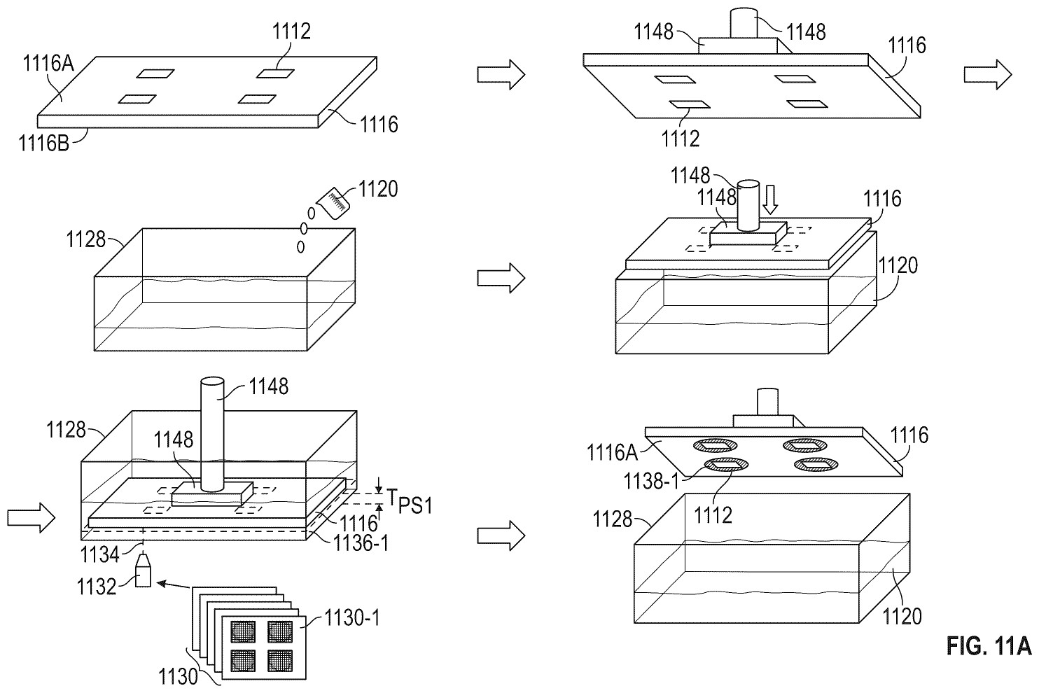

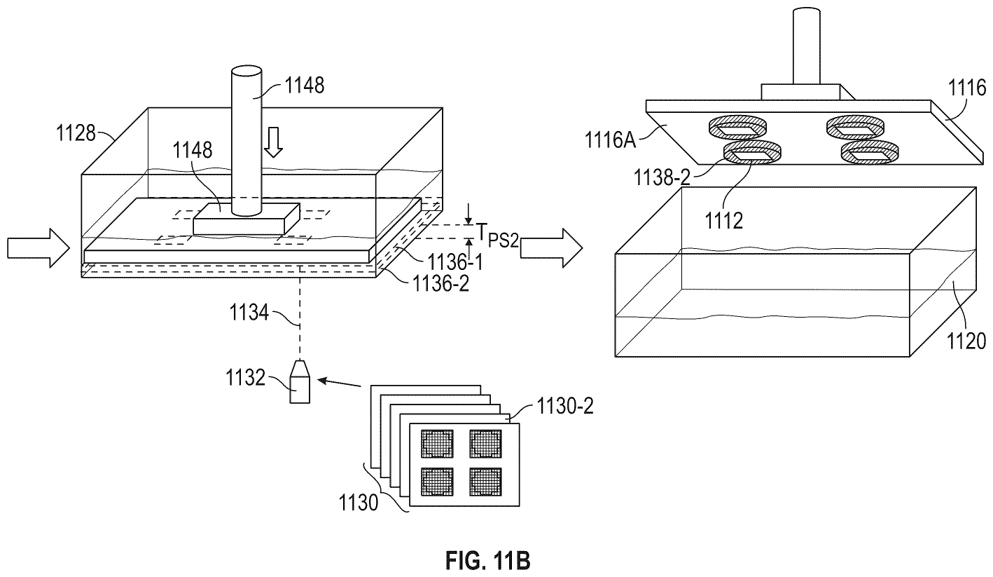

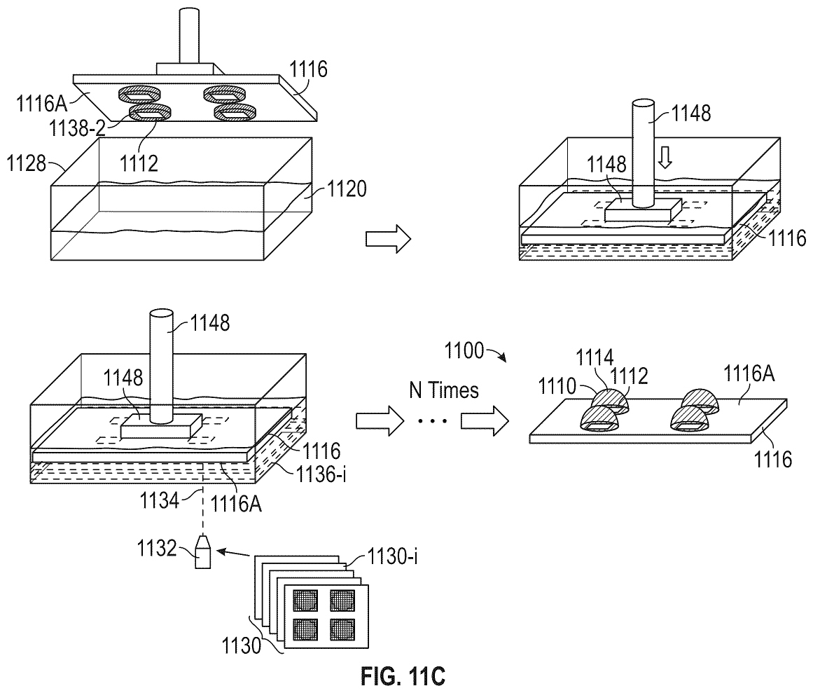

FIGS. 11A to 11C describe a layer-by-layer stereolithography (SLA) printing method to fabricate lenses 1114 and corresponding LED packages 1110 for an LED panel 1100. As will be discussed in greater detail herein, the layer-by-layer SLA printing method includes rastering of a focused UV beam 1134 onto a bottom surface of a resin tank 1128 in a successive, sequential, and layer-by-layer manner. The rastering of the focused UV beam 1134 is in accordance with corresponding ones of raster graphics 1130. The bottom surface of the resin tank 1128 is transparent so that the focused UV beam 1134 may expose a precursor solution 1120 within the resin tank 1128 and under a top surface 1116A of a submount 1116. The submount 1116 is held within the resin tank 1128 using a stage 1148 that mechanically couples to the submount 1116 in a position opposite the top surface 1116A. In this manner, the top surface 1116A faces and remains parallel to the bottom surface of the resin tank 1128 as the stage 1148 moves the submount 1116 along the Z-axis. Accordingly, the precursor solution 1120 is cured in a layer-by-layer manner to form continuous lenses 1114 over predetermined areas of the top surface 1116A of the submount 1116 as the submount 1116 moves along the Z-axis. The lenses 1114 thereby encapsulate corresponding LED chips 1112 to form the LED packages 1110 of the LED panel 1100.

FIG. 11A shows the submount 1116 positioned relative to the resin tank 1128 to form a first precursor solution layer 1136-1 of the precursor solution 1120 between the top surface 1116A of the submount 1116 and the bottom surface of the resin tank 1128 that is cured using the focused UV beam 1134 to form a first raster layer 1138-1 in the layer-by-layer SLA printing method. In this regard, FIG. 11A corresponds with placing the submount 1116 above the bottom surface of the resin tank 1128 with the top surface 1116A of the submount 1116 facing the bottom surface of the resin tank 1128 so that the first precursor solution layer 1136-1 of the precursor solution 1120 remains between the top surface 1116A of the submount 1116 and the bottom surface of the resin tank 1128. FIG. 11A further corresponds with rastering of the focused UV beam 1134 onto the bottom surface of the resin tank 1128 in a successive, sequential, and layer-by-layer manner to form the first raster layer 1138-1 that forms part of the lenses 1114.

The submount 1116 is positioned within the resin tank 1128 and at a certain height above the bottom surface of the resin tank 1128 using the stage 1148. In this manner, the top surface 1116A of the submount 1116 faces and remains parallel to the bottom surface of the resin tank 1128 as the stage 1148 moves the submount 1116 along the Z-axis. First, the stage 1148 is utilized to lower the submount 1116 within the resin tank 1128 such that the first precursor solution layer 1136-1 of the precursor solution 1120 is maintained between the submount 1116 and the bottom surface of the resin tank 1128. A UV source 1132 is positioned to provide a focused UV beam 1134. The focused UV beam 1134 is used to expose portions of the first precursor solution layer 1136-1 of the precursor solution 1120 to selectively cure portions thereof in accordance with a first raster graphic 1130-1 to form the first raster layer 1138-1. The first raster layer 1138-1 disposes, at least partially, over and above each of the LED chips 1110, over the top surface 1116A of the submount 1116 to form part of the lenses 1114. For illustrative purposes, the submount 1116 is shown removed from the resin tank 1128 to show the first raster layer 1138-1. In practice, the submount 1116 may or may not be removed from the resin tank 1128 before additional raster layers are formed.

FIG. 11B illustrates the submount 1116 after formation of a second raster layer 1138-2 as part of the layer-by-layer SLA printing method. In this regard, FIG. 11B corresponds with utilizing the stage 1148 to position the submount 1116 within the resin tank 1128 such that a second precursor solution layer 1136-2 of the precursor solution 1120 is maintained between top surfaces of the first raster layer 1138-1 and the bottom surface of the resin tank 1128. FIG. 11B further corresponds with using the focused UV beam 1134 to selectively form the second raster layer 1138-2 that forms part of the lenses 1114. As the submount 1116 moves along the Z-axis within the resin tank 1128, the second precursor solution layer 1136-2 of the precursor solution 1120 accumulates between the submount 1116 and the bottom surface of the resin tank 1128. The layer-by-layer elevation of the submount 1116 is followed by the exposure of successive layers 1136 of the precursor solution 1120 to the focused UV beam 1134 to fabricate interlaced and unified raster layers 1138. In this regard, the focused UV beam 1134 is used to expose and cure predetermined areas in accordance with a second raster graphic 1130-2. As with FIG. 11A, the submount 1116 is shown removed from the resin tank 1128 in FIG. 11B to show the second raster layer 1138-2. In practice, the submount 1116 may or may not be removed from the resin tank 1128 before additional raster layers are formed.

FIG. 11C illustrates fabrication of the LED panel 1100 by repeating the fabrication step as illustrated by FIG. 11B a selected number N of times to fabricate lenses 1114 having interlaced raster layers as part of the layer-by-layer SLA printing method. In FIG. 11C, the submount 1116 is initially shown removed from the resin tank 1128 for illustrative purposes. As mentioned above, the submount 1116 may or may not remain in the resin tank 1128 throughout the formation of the lenses 1114, depending on the embodiment. FIG. 11C represents repeating the fabrication step of FIG. 11B a selected number N to fabricate the LED panel 1100. In FIG. 11C, the stage 1148 is utilized to position the submount 1116 along the Z-axis so that an ith precursor solution layer 1136-i of the precursor solution 1120 (where i is a number and 2<i≤N) is positioned between the submount 1116 and the bottom surface of the resin tank 1128. The layer-by-layer elevation of the submount 1116 is followed by rastering each of the successive precursor solution layers 1136-i with the focused UV beam 1134 in accordance with corresponding ones of the raster graphics 1130-i. In this manner, raster layers 1138 may be successively interlaced and unified to form the lenses 1114 that encapsulate LED chips 1112 of the LED packages 1110. FIG. 11C further illustrates the LED panel 1100 having the plurality of LED packages 1110 after removing of any remaining precursor solution 1120 from the resin tank 1128 and removing the LED panel 1100 from the resin tank 1128. Any optional post processing treatment of the LED panel 1100 may also be performed.

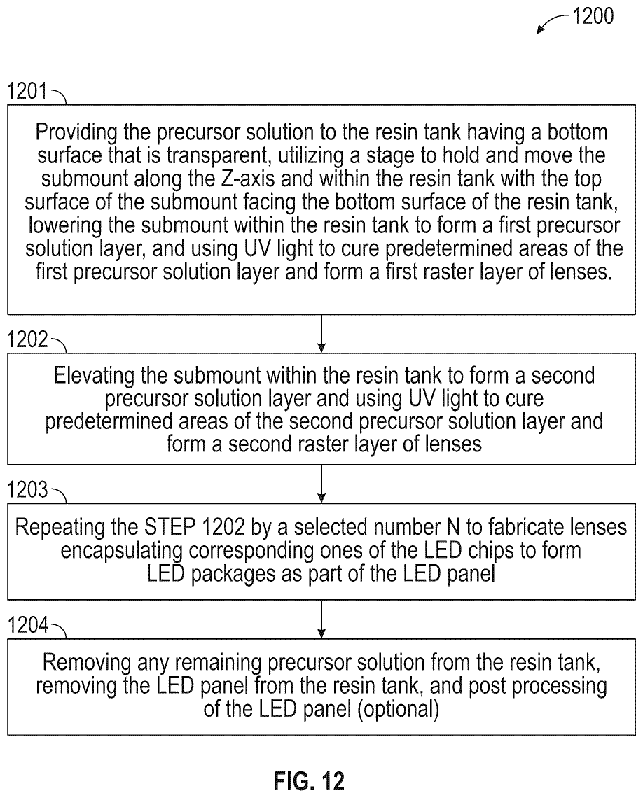

FIG. 12 illustrates an exemplary process flow diagram 1200 describing the general fabrication steps of the layer-by-layer SLA printing method of FIGS. 11A to 11C. In FIG. 12, step 1201 generally corresponds with FIG. 11A for providing the precursor solution 1120 to the resin tank 1128 having a bottom surface that is transparent, utilizing a stage 1148 to hold and move the submount 1116 along the Z-axis and within the resin tank 1128 with the top surface 1116A of the submount 1116 facing the bottom surface of the resin tank 1128, lowering the submount 1116 within the resin tank 1128 to form a first precursor solution layer 1136-1, and using a focused UV beam 1134 to cure predetermined areas of the first precursor solution layer 1136-1 and form a first raster layer 1138-1. Step 1202 generally corresponds with FIG. 11B for elevating the submount 1116 within the resin tank 1128 to form a second precursor solution layer 1136-2 and using UV light to cure predetermined areas of the second precursor solution layer 1136-2 and form a second raster layer 1138-2. Step 1203 generally corresponds with FIG. 11C for repeating the step 1202 a selected number N of times to fabricate lenses 1114 encapsulating corresponding LED chips 1112 to form LED packages 1110 of the LED panel 1100. Step 1204 also corresponds with FIG. 11C for removing the LED panel 1100 from the resin tank 1128 and any optional post processing.

As described above, various additive and/or layer-by-layer fabrication techniques are provided for forming LED lenses as primary optics in LED packages. The LED lenses are integrated as portions of the LED packages and may also encapsulate corresponding LED chips. In this manner, the lenses may be formed in sequential layers so that the LED chips are effectively embedded within materials of the lenses. Such additive fabrication techniques, including the layer-by-layer additive printing method of FIGS. 3A to 4, the injection printing method of FIGS. 5A to 6, the layer-by-layer DLP method of FIGS. 7A to 8, the SLA printing method of FIGS. 9A to 10, and/or the LCD printing method of FIGS. 11A to 12, may be implemented to form complex lens shapes as primary optics in LED packages. As indicated above, such primary optics may form materials that serve as primary encapsulants of the LED chips. For example, the materials may cover or directly cover portions of LED chips and underlying submounts.

As described herein, the principles of the present disclosure provide the ability to have complex optical shapes typically achieved by secondary optics in conventional applications. Complex optical shapes may include pockets or cavities that are embedded within a material of a lens to form integrated index of refraction steps and/or interfaces. Such pockets may form air pockets or the pockets may be filled with another material, such as a gas, liquid, gel, or generally solid material that is different than the material of the lens. For air pocket embodiments, the additive fabrication techniques are formed sequentially according to the desired shape of the pocket. For embodiments where the pocket is filled with another material, the additive formation may be paused when the pocket is still open from a top surface and a fill material may be dispensed or otherwise provided within the pocket. After the fill material is provided, the additive fabrication may resume to enclose the pocket.

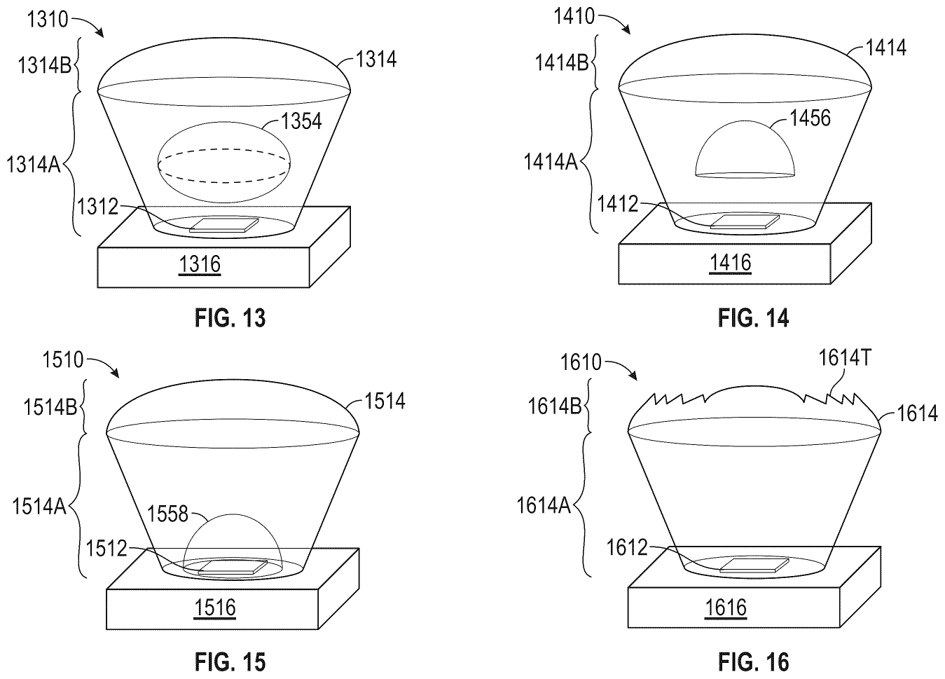

As described above, lenses with complex optical shapes may be formed by additive fabrication techniques directly on submounts and/or LED panels. Accordingly, such lenses with complex optical shapes may be integrated within LED packages without needing adhesive materials therebetween associated with bonding pre-formed lens structures to LED packages. FIGS. 13 to 22 represent exemplary LED packages with lenses having pockets and/or other complex shapes that may be formed by any of the additive fabrication techniques described above for FIGS. 3A to 12.

FIG. 13 is a perspective view of an LED package 1310 with a lens 1314 having a pocket 1354 formed within a material of the lens 1314 according to principles of the present disclosure. The LED package 1310 includes a submount 1316 and an LED chip 1312 mounted thereon. As illustrated, the lens may have a base portion 1314A with a width or diameter that increases with distance away from the submount 1316 and a top portion 1314B that is generally curved. In this manner, an outer wall 1314W of the base portion 1314A may be angled outward from the submount 1316 to direct light toward the top portion 1314B. By forming the lens 1314 according to additive principles described above, the base portion 1314A and the top portion 1314B are continuous with one another and without seams associated with two separately formed elements that are joined together. The pocket 1354 may be positioned within a continuous material of the lens 1314 such that the pocket 1354 is entirely embedded within the lens 1314. As used herein, a continuous material of the lens 1314 refers to the material being continuous and without seams associated with bonding or otherwise joining two lens portions together. The pocket 1354 may form an air pocket or the pocket may retain a fill material as described above. In this manner, the pocket 1354 may provide an index of refraction step within an interior of the lens 1314 that is configured to direct light by refraction and/or reflection in desired directions within the lens 1314. Since the pocket 1354 is formed according to the additive principles described above, precise control of the location and dimensions of the pocket 1354 may be realized. In certain embodiments, the pocket 1354 may be suspended within the material of the lens 1314 in a position that is spaced above the LED chip 1312. In FIG. 13, the pocket 1354 is suspended within the base portion 1314A in a position that is close to the LED chip 1312 for receiving light. In certain embodiments, the pocket 1354 forms an ellipsoid shape with a longest dimension in a range of 25 microns (μm) to 4000 μm. As used herein, an ellipsoid shape is inclusive of spheres and non-spherical shapes.

FIG. 14 is a perspective view of an LED package 1410 that is similar to the LED package 1310 of FIG. 13, except a pocket 1456 in a lens 1414 of the LED package 1410 is formed with a hemiellipsoid shape. The LED package 1410 includes a submount 1416 and an LED chip 1412 mounted thereon. As illustrated, the lens 1414 may have a base portion 1414A with a width or diameter that increases with distance away from the submount 1416 and a top portion 1414B that is generally curved in a similar manner as FIG. 13. The pocket 1456 forms the hemiellipsoid shape with a generally planar surface closest to the LED chip 1412. As with FIG. 13, the pocket 1456 may be entirely embedded within a continuous material of the lens 1414 and positioned within the base portion 1414A, and the pocket 1456 may form an air pocket or a fill material may reside within the pocket 1456.

FIG. 15 is a perspective view of an LED package 1510 that is similar to the LED package 1310 of FIG. 13, except a pocket 1558 of the LED package 1510 is formed proximate a submount 1516. In this manner, the pocket 1558 is formed about an LED chip 1512 such that a material of a lens 1514 is spaced from the LED chip 1512. Accordingly, the LED chip 1512 is effectively encapsulated by the pocket 1558, which is in turn encapsulated by the lens 1514. As illustrated, the lens 1514 may have a base portion 1514A with a width or diameter that increases with distance away from the submount 1516 and a top portion 1514B that is generally curved in a similar manner as FIG. 13. The pocket 1558 forms a hemiellipsoid shape with a generally planar surface on the submount 1516 such that a curved upper surface of the hemiellipsoid shape is curved to direct light into the lens 1514. The pocket 1558 may form an air pocket or a fill material may reside within the pocket 1558.

FIG. 16 is a perspective view of an LED package 1610 that is similar to the LED package 1310 of FIG. 13, except a top surface 1614T of a lens 1614 in FIG. 16 forms a Fresnel lens. According to the additive principles of the present disclosure, complex shapes, such as a Fresnel lens for the top surface 1614T, may be integrated within a continuous material of the lens 1614. As illustrated, the lens 1614 may have a base portion 1614A with a width or diameter that increases with distance away from a submount 1616 in a similar manner as FIG. 13 and a top portion 1614B with the top surface 1614T described above. In certain embodiments, the top surface 1614T with the Fresnel lens may be used in combination with any of the pockets as described herein.

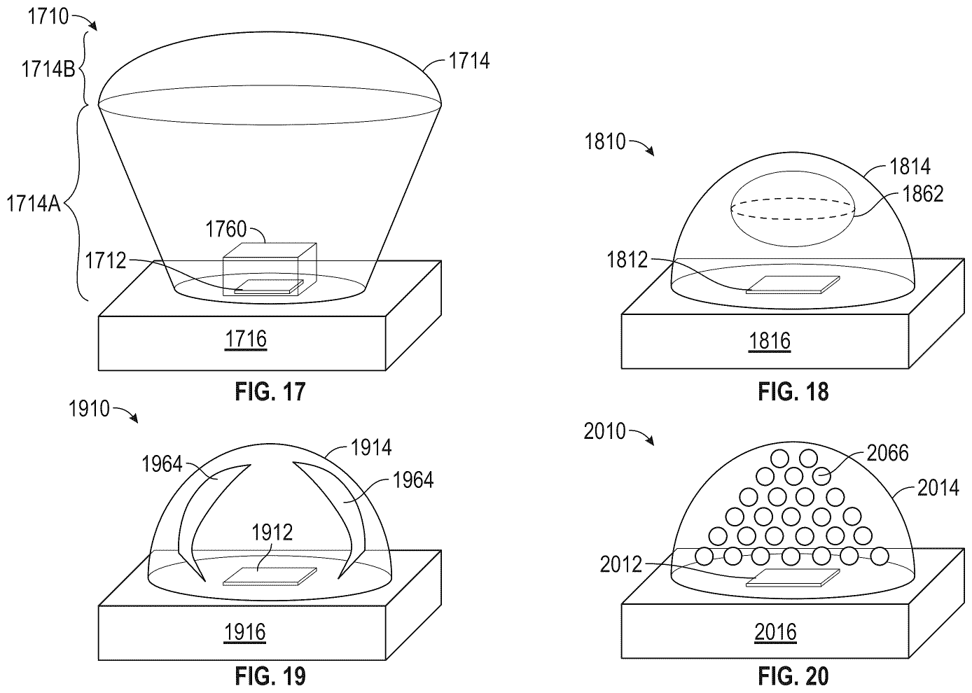

FIG. 17 is a perspective view of an LED package 1710 that is similar to the LED package 1510 of FIG. 15 except a pocket 1760 with a cuboid shape is formed proximate a submount 1716. The cubic shape provides a different light pattern for light entering the lens 1714 from an LED chip 1712 than the hemiellipsoid shape of the pocket 1558 of FIG. 15. The additive fabrication techniques as described herein provide the ability to easily provide various shapes of the pocket 1760. As illustrated, the lens 1714 may have a base portion 1714A with a width or diameter that increases with distance away from a submount 1716 in a similar manner as FIG. 13 and a top portion 1714B that is above the base portion 1714A.

FIG. 18 is a perspective view of an LED package 1810 that is similar to the LED package 1310 of FIG. 13 for embodiments with a lens 1814 that is generally curved. As illustrated, the lens 1814 forms a hemiellipsoid or hemispherical shape on a surface of a submount 1816 of the LED package 1810. A pocket 1862 that forms an ellipsoid shape is provided within the continuous material of the lens 1814 in a manner as described above for the LED package 1310 of FIG. 13.

FIG. 19 is a perspective view of an LED package 1910 that is similar to the LED package 1810 of FIG. 18 for embodiments with multiple pockets 1964. As illustrated, an LED chip 1912 is on a submount 1916 of the LED package 1910 and multiple pockets 1964 are formed within a material of the lens 1914. In FIG. 19, the pockets 1964 are provided proximate perimeter sides of the lens 1914. In the manner, the index of refraction step provided may effectively direct and/or channel wide angle light from the LED chip 1912 in a direction normal to a surface of the submount 1916. Accordingly, the pockets 1964 may be positioned to redirect lateral light to provide an emission pattern with a more narrow beam.

FIG. 20 is a perspective view of an LED package 2010 that is similar to the LED package 1910 of FIG. 19 for embodiments where multiple pockets 2066 form a periodic array within a lens 2014. As illustrated, an LED chip 2012 is on a submount 2016 of the LED package 2010 and the array of pockets 2066 are formed within a continuous material of the lens 2014. The additive fabrication techniques as described here allow precise control of the position of each pocket 2066. In FIG. 20, the pockets 2066 are formed in rows with a common pitch and numbers of pockets 2066 in rows progressively decrease with distance away from the submount 2016.

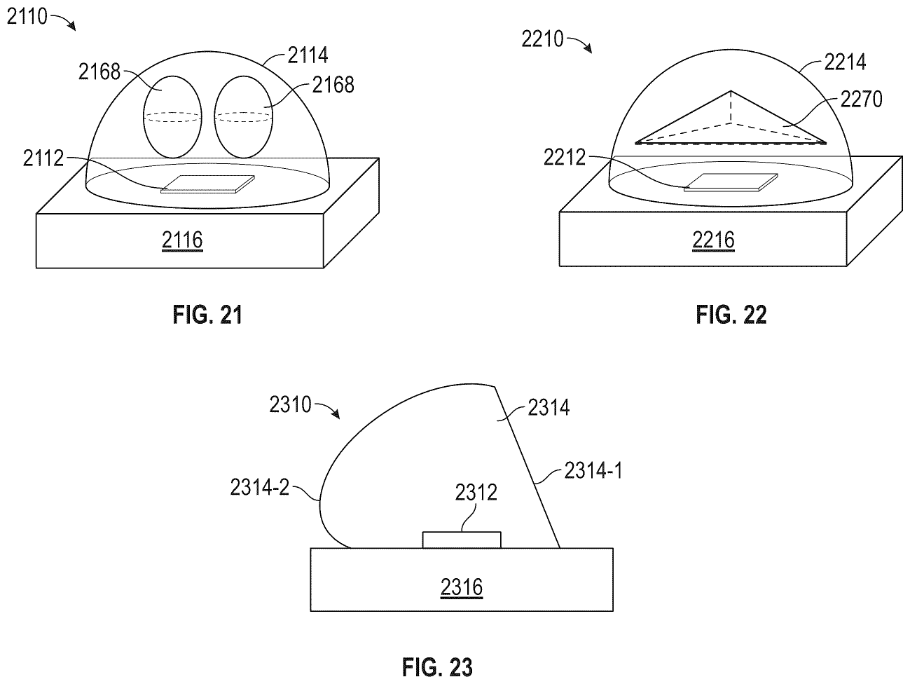

FIG. 21 is a perspective view of an LED package 2110 that is similar to the LED package 1910 of FIG. 19 for embodiments that include multiple pockets 2168 with ellipsoid shapes. As illustrated, an LED chip 2112 is on a submount 2116 of the LED package 2110 and the multiple pockets 2168 are formed within a continuous material of the lens 2014. The multiple pockets 2168 with ellipsoid shapes may be positioned adjacent one another and over the LED chip 2112, and portions of the lens 2114 between the pockets 2168 may be positioned centrally over the LED chip 2112 for providing a desired light emission pattern.

FIG. 22 is a perspective view of an LED package 2210 that is similar to the LED package 1310 of FIG. 13 for embodiments where a pocket 2270 forms a non-circular geometric shape. As illustrated, an LED chip 2212 is on a submount 2216 of the LED package 2210 and the pocket 2270 is formed within a continuous material of the lens 2214. In FIG. 22, the pocket 2270 forms a pyramidical shape with a base that is closest to the LED chip 2212. In this manner, light from the LED chip 2212 may interact with the pocket 2270 and be redirected in a desired emission pattern.

FIG. 23 is a cross-sectional view of an LED package 2310 that is similar to the LED package 1310 of FIG. 13 for embodiments with a lens 2314 having an asymmetric shape. As illustrated, an LED chip 2312 is on a submount 2316 of the LED package 2310 in a similar manner as previous embodiments. The lens 2314 may be formed according to the additive manufacturing principles described herein. Accordingly, complex shapes are available for shaping light emissions in a desired direction. In the example of FIG. 23, the lens 2314 is configured to preferentially direct light away from a first wall 2314-1 and toward a second wall 2314-2. The first wall 2314-1 may be formed with an angle that tapers toward a center of the LED package 2310 with distance away from the submount 2316. In certain embodiments, the first wall 2314-1 may form a planar surface. The second wall 2314-2 may form a curved surface that curves outward from the first wall 2314-1 and from a surface of the submount 2316. In this regard, a shape of the lens 2314 is configured to provide an emission pattern with peak or highest concentrations of emissions that are off center. Such an emission pattern may be suited for elevated displays. The asymmetric shape of the lens 2314 is provided as an example. With the additive fabrication techniques described herein, the shape of the lens may be readily altered to target different applications with different emission patterns. Additionally, any of the pockets as described above may readily be incorporated into the lens 2314.

It is contemplated that any of the foregoing aspects, and/or various separate aspects and features as described herein, may be combined for additional advantage. Any of the various embodiments as disclosed herein may be combined with one or more other disclosed embodiments unless indicated to the contrary herein.

Those skilled in the art will recognize improvements and modifications to the preferred embodiments of the present disclosure. All such improvements and modifications are considered within the scope of the concepts disclosed herein and the claims that follow.

What is claimed is:

1. A light-emitting diode (LED) package comprising:
a support structure;
an LED chip on the support structure; and
a lens on the support structure, the lens forming an encapsulant for the LED chip, the lens forming a pocket entirely embedded within a continuous material of the lens, and the pocket forming an index of refraction step with the continuous material of the lens.

2. The LED package of claim 1, wherein a longest dimension of the pocket is in a range from 25 microns (μm) to 4000 μm.

3. The LED package of claim 1, wherein the pocket forms an ellipsoid shape within the lens.

4. The LED package of claim 1, wherein the pocket forms an air pocket within the lens.

5. The LED package of claim 1, wherein the pocket retains a fill material that is different than the continuous material of the lens.

6. The LED package of claim 1, wherein the lens forms a base portion on the support structure and a top portion that is spaced from the support structure by the base portion, the base portion having a width that increases with distance from the support structure.

7. The LED package of claim 6, wherein a top surface of the top portion of the lens forms a Fresnel lens.

8. The LED package of claim 1, wherein the pocket is a first pocket and the lens further forms a second pocket that is embedded within the continuous material of the lens.

9. The LED package of claim 1, wherein the pocket is one of an array of pockets that form a periodic array within the continuous material of the lens.

10. The LED package of claim 1, wherein the lens forms an asymmetric shape relative to the submount.

11. A light-emitting diode (LED) package comprising:
a support structure;
an LED chip on the support structure; and
a lens formed directly on the support structure, the lens forming a pocket on the support structure that separates the LED chip from a material of the lens.

12. The LED package of claim 11, wherein the pocket forms a hemiellipsoid shape about the LED chip.

13. The LED package of claim 11, wherein the pocket forms a cuboid shape.

14. The LED package of claim 11, wherein the pocket forms an air pocket about the LED chip.

15. The LED package of claim 11, wherein the pocket retains a fill material that is different than the material of the lens.

16. A method of manufacturing a light-emitting diode (LED) package, the method comprising:
providing a submount with an LED chip mounted thereon; and
forming a lens on the submount and the LED chip by additive formation, the additive formation comprising progressively curing a precursor material of the lens in a direction away from the submount.

17. The method of claim 16, wherein progressively curing the precursor material comprises progressively curing progressive layers of the precursor material in the direction away from the submount.

18. The method of claim 16, wherein progressively curing the precursor material comprises continuously curing the precursor material in the direction away from the submount.

19. The method of claim 16, further comprising forming a pocket in lens, the pocket comprising air or a fill material that is a different material than the lens.

20. The method of claim 16, wherein the submount and LED chip are part of an LED panel, and multiple lenses are formed by progressively curing the precursor material of the lens in the direction away from the submount.
